(19) United States
(12) Patent Application Publication
(10) Pub. No.: US 2025/0024712 A1
(43) Pub. Date: Jan. 16, 2025

(54) DISPLAY DEVICE AND MOBILE ELECTRONIC DEVICE INCLUDING THE SAME

(71) Applicant: Samsung Display Co., LTD., Yongin-si (KR)

(72) Inventors: Ki Hyun PYO, Yongin-si (KR); Kyung Bae KIM, Yongin-si (KR); Do Yeong PARK, Yongin-si (KR)

(73) Assignee: Samsung Display Co., LTD., Yongin-si (KR)

(21) Appl. No.: 18/590,969

(22) Filed: Feb. 29, 2024

(30) Foreign Application Priority Data
Jul. 10, 2023 (KR) 10-2023-0089153

(51) Int. Cl. H10K 59/122; G09G 3/3233; H10K 59/121; H10K 59/131

(52) U.S. Cl. CPC H10K 59/122; G09G 3/3233; H10K 59/1213; H10K 59/131; G09G 2320/0214

(57) ABSTRACT

A display device that may include a substrate, a driving element layer disposed on the substrate, and a light emitting element layer disposed on the driving element layer. The light emitting element layer may include a pixel defining layer including a plurality of openings defining a corresponding plurality of pixels, a first electrode disposed in each of the pixels and including a first portion covered by the pixel defining layer and a second portion extending from the first portion and corresponding to one of the openings of each of the pixels,, an intermediate layer covering the second portion of the first electrode in the openings of each of the pixels, covering the pixel defining layer between neighboring pixels, and including an electrically disconnected portion corresponding to the heating wiring.

### CROSS-REFERENCE TO RELATED APPLICATIONS

This application claims priority under 35 U.S.C. 119 from Korean Patent Application No. 10-2023-0089153 filed on Jul. 10, 2023 in the Korean Intellectual Property Office, the entire contents of which are incorporated herein by reference.

### BACKGROUND

### 1. Technical Field

The disclosure relates to a display device and a mobile electronic device including the same.

### 2. Description of the Related Art

A wearable device that forms a focus at a short distance from a user's eyes is being developed in the form of glasses or a helmet. For example, the wearable device may be a head mounted display (HMD) or augmented reality (AR) glasses. Such a wearable device provides an AR screen or a virtual reality (VR) screen to a user.

A wearable device such as an HMD or AR glasses may be required to have a display specification of at least 2000 pixels per inch (PPI) so that a user can use it for a long time without dizziness. To this end, organic light emitting diode on silicon (OLEDoS) technology, which may be a small, high-resolution organic light emitting display device, is being proposed. OLEDoS is a technology for placing an organic light emitting diode (OLED) on a semiconductor wafer substrate on which a complementary metal oxide semiconductor (CMOS) may be disposed.

Since a distance between pixels may be reduced in a display panel to which the OLEDoS technology has been applied, an unintended leakage current may be generated between adjacent pixels. The leakage current may be generated through some conductive layers of an intermediate layer disposed between a pixel electrode (e.g., an anode) and a common electrode (e.g., cathode). The leakage current may be a cause of color crosstalk between adjacent pixels.

### SUMMARY

Aspects of the disclosure provide a display device in which at least a portion of an intermediate layer disposed between a pixel electrode and a common electrode may be electrically disconnected between adjacent pixels to prevent leakage current and color crosstalk, and a mobile electronic device including the display device.

According to an embodiment of the disclosure, a display device may include a substrate, a driving element layer disposed on the substrate, and a light emitting element layer disposed on the driving element layer. The light emitting element layer may include a pixel defining layer including a plurality of openings defining a corresponding plurality of pixels, a first electrode disposed in each of the plurality of pixels and including a first portion covered by the pixel defining layer and a second portion extending from the first portion and corresponding to one of the openings, a heating wiring disposed on an upper surface of the pixel defining layer to surround at least a portion of each of the plurality of openings, a connection electrode connecting the heating wiring and the first portion of the first electrode through a contact hole penetrating the pixel defining layer, an intermediate layer covering the second portion of the first electrode and the pixel defining layer disposed between neighboring pixels, the intermediate layer including an electrically disconnected portion corresponding to the heating wiring in a plan view, and a second electrode being continuous and covering portions of the intermediate layer disposed in the openings of each of the pixels and covering portions of the intermediate layer and the heating wiring disposed between the neighboring pixels.

The driving element layer may include a joule heating driver disposed to correspond to a non-display area of the substrate and configured to sequentially supply a heating scan signal to a plurality of heating scan wirings disposed in a display area of the substrate.

The driving element layer may further include a switching circuit disposed to correspond to the non-display area of the substrate and configured to supply a joule heating voltage to a plurality of heating voltage supply wirings disposed in the display area of the substrate in synchronization with a timing at which the joule heating driver outputs the heating scan signal.

The switching circuit may include a plurality of switching transistors electrically connected one-to-one to the plurality of heating voltage supply wirings, and each of the plurality of switching transistors may be turned on in response to a heating control signal and configured to output the joule heating voltage in case of being turned on.

The heating control signal may be synchronized with the heating scan signal. The heating voltage supply wirings may intersect the heating scan wirings.

The driving element layer may further include a pixel driving circuit disposed in the display area of the substrate to correspond to each of the pixels, and the pixel driving circuit may include a driving transistor supplying a designated driving current to a first node electrically connected to the first electrode based on a data signal input from a data line, and a heating transistor turned on in response to the heating scan signal input from a heating scan wiring and supplying the joule heating voltage input from a heating voltage supply wiring to the first node in case of being turned on.

The heating wiring may be configured to receive the joule heating voltage via the first electrode and the connection electrode.

A resistance of the heating wiring may be greater than a resistance of the first electrode and a resistance of the connection electrode.

The intermediate layer may include at least one conductive layer including a portion electrically disconnected at a location corresponding to the heating wiring, and the at least one conductive layer may comprise a layer selected from a hole injection layer, a hole transport layer, an electron transport layer, a charge generation layer, and a P-doped layer.

In a plan view, the heating wiring may surround each of the openings of the pixel defining layer, and the heating wiring may include an open slit area open at a specific lateral direction.

The intermediate layer and the second electrode may be continuous without being electrically disconnected at a location corresponding to the open slit area.

According to an embodiment of the disclosure, a mobile electronic device may include a display panel, the display panel may include a substrate, a driving element layer disposed on the substrate, and a light emitting element layer disposed on the driving element layer. The light emitting element layer may include a pixel defining layer including a plurality of openings defining a corresponding plurality of pixels, a first electrode disposed in each of the plurality of pixels and including a first portion covered by the pixel defining layer and a second portion extending from the first portion and corresponding to one of the openings, a heating wiring disposed on an upper surface of the pixel defining layer to surround at least a portion of each of the plurality of openings, a connection electrode connecting the heating wiring and the first portion of the first electrode through a contact hole penetrating the pixel defining layer, an intermediate layer covering the second portion of the first electrode and the pixel defining layer disposed between neighboring pixels, the intermediate layer including an electrically disconnected portion corresponding to the heating wiring in a plan view, and a second electrode being continuous and covering portions of the intermediate layer disposed in the openings of each of the pixels and covering portions of the intermediate layer and the heating wiring disposed between the neighboring pixels.

The driving element layer may include a joule heating driver disposed to correspond to a non-display area of the substrate and configured to sequentially supply a heating scan signal to a plurality of heating scan wirings disposed in a display area of the substrate.

The driving element layer may further include a switching circuit disposed to correspond to the non-display area of the substrate and configured to supply a joule heating voltage to a plurality of heating voltage supply wirings disposed in the display area of the substrate in synchronization with a timing at which the joule heating driver outputs the heating scan signal.

The switching circuit may include a plurality of switching transistors electrically connected one-to-one to the plurality of heating voltage supply wirings, and each of the plurality of switching transistors may be turned on in response to a heating control signal and configured to output the joule heating voltage in case of being turned on.

The heating control signal may be synchronized with the heating scan signal.

The heating voltage supply wirings may intersect the heating scan wirings.

The driving element layer may further include a pixel driving circuit disposed in the display area of the substrate to correspond to each of the pixels, and the pixel driving circuit may include a driving transistor supplying a designated driving current to a first node electrically connected to the first electrode based on a data signal input from a data line, and a heating transistor turned on in response to the heating scan signal input from a heating scan wiring and supplying the joule heating voltage input from a heating voltage supply wiring to the first node in case of being turned on.

The heating wiring may be configured to receive the joule heating voltage via the first electrode and the connection electrode.

However, aspects of the disclosure may not be restricted to those set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of a display panel according to an embodiment;

FIG. 3 is a schematic block diagram configuration of the display device according to the embodiment;

FIG. 4 is a schematic block diagram configuration of a joule heating driver and a switching circuit according to an embodiment;

FIG. 5 is a schematic diagram of an equivalent circuit of a pixel of the display device according to the embodiment;

FIG. 6 is a schematic cross-sectional view of a portion of the display panel of the display device according to the embodiment;

FIG. 7 is a cross-sectional view schematically illustrating the stacked structure of a light emitting element according to an embodiment;

FIG. 8 is a cross-sectional view schematically illustrating the stacked structure of a light emitting element according to an embodiment;

FIG. 9 is a schematic plan view of a portion of a display area of a display panel according to an embodiment;

FIG. 10 is a cross-sectional view schematically illustrating the cross-sectional structure of adjacent pixels illustrated in FIG. 9;

FIG. 11 is a flowchart illustrating a method of manufacturing the display panel illustrated in FIG. 10;

FIGS. 12 through 15 are schematic cross-sectional views sequentially illustrating a method of manufacturing a display panel according to an embodiment;

FIG. 16 illustrates an embodiment in which a heating wiring illustrated in FIG. 9 includes an open slit area in a specific lateral direction of each pixel;

FIG. 17 is a flowchart illustrating a method of manufacturing the display panel illustrated in FIG. 16;

FIGS. 18 through 21 are schematic cross-sectional views sequentially illustrating a method of manufacturing a display panel according to an embodiment; and

FIG. 22 is an example view of a wearable device including a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, specific embodiments will be described with reference to the accompanying drawings.

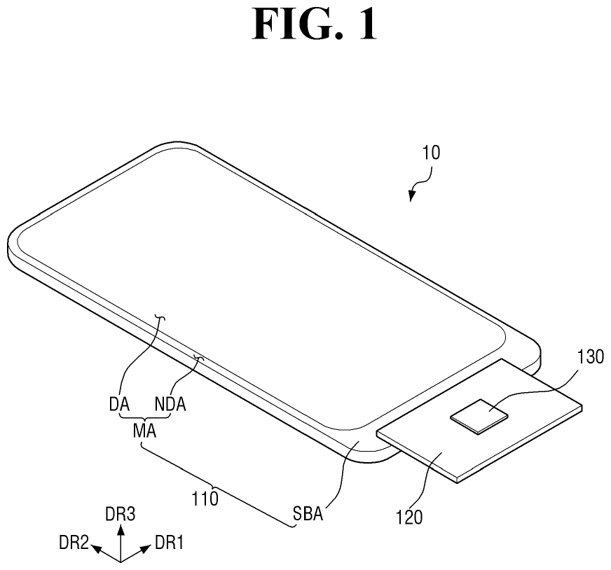

FIG. 1 is a perspective view of a display device 10 according to an embodiment.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display part of a television, a notebook computer, a monitor, a billboard, or an Internet of things (IoT) device. For another example, the display device 10 may be applied to wearable devices such as smart watches, watch phones, glasses-type displays, and head mounted displays (HMDs).

The display device 10 may have a planar shape similar to a quadrangle. For example, the display device 10 may have a planar shape similar to a quadrangle having short sides in a first direction DR1 and long sides in a second direction DR2. The display device 10 may have a planar shape similar to a quadrangle having long sides in the first direction DR1 and short sides in the second direction DR2. In FIG. 1, DR3 represents a normal direction perpendicular to a plane defined by the first direction DR1 and the second direction DR2. Each corner where a short side meets a long side may be rounded with a curvature (e.g., predetermined or selectable curvature) or may be right-angled. The planar shape of the display device 10 may not be limited to a quadrangular shape but may also be similar to other polygonal shapes, a circular shape, or an elliptical shape.

The display device 10 may include a display panel 110, a circuit board 120, and a power supply part 130.

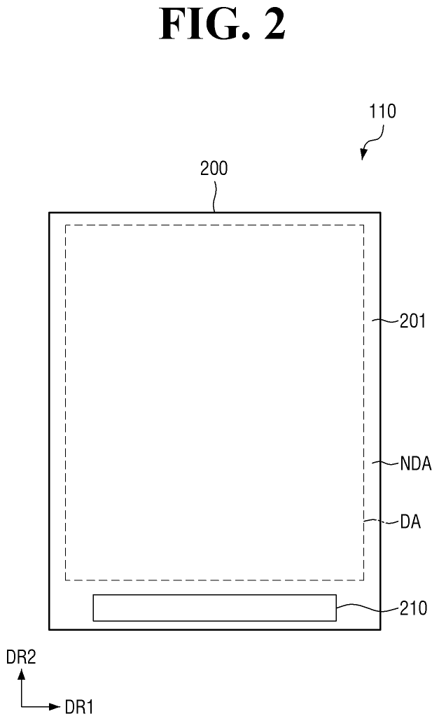

The display panel 110 may be a display panel 110 using a semiconductor wafer substrate 200 (see FIG. 2) as a base substrate. The display panel 110 may include a main area MA and a sub-area SBA.

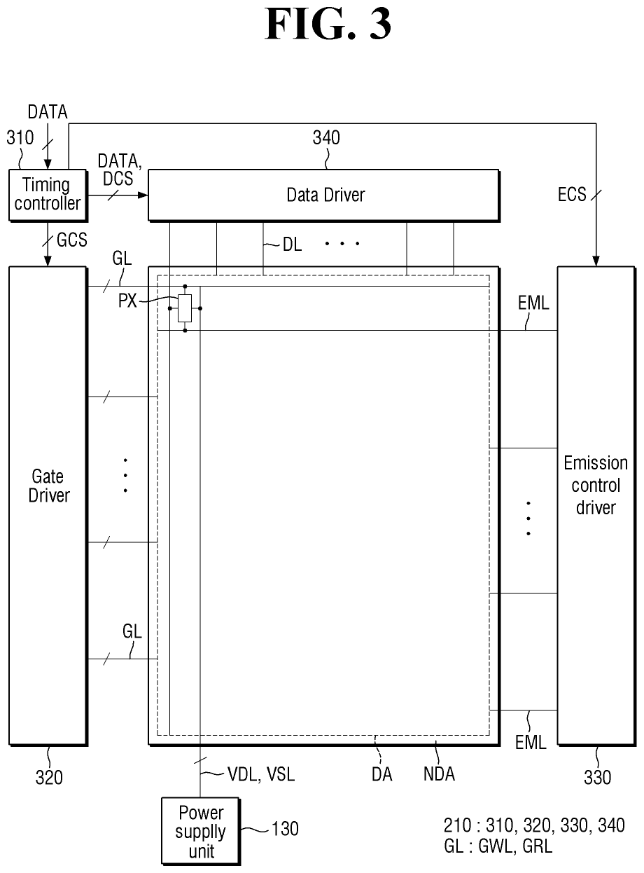

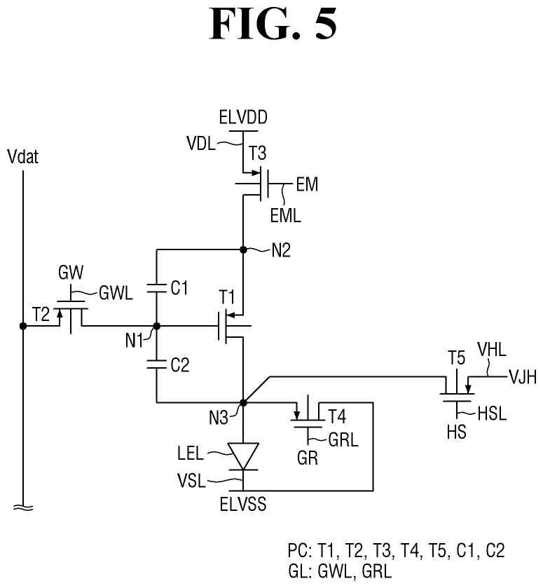

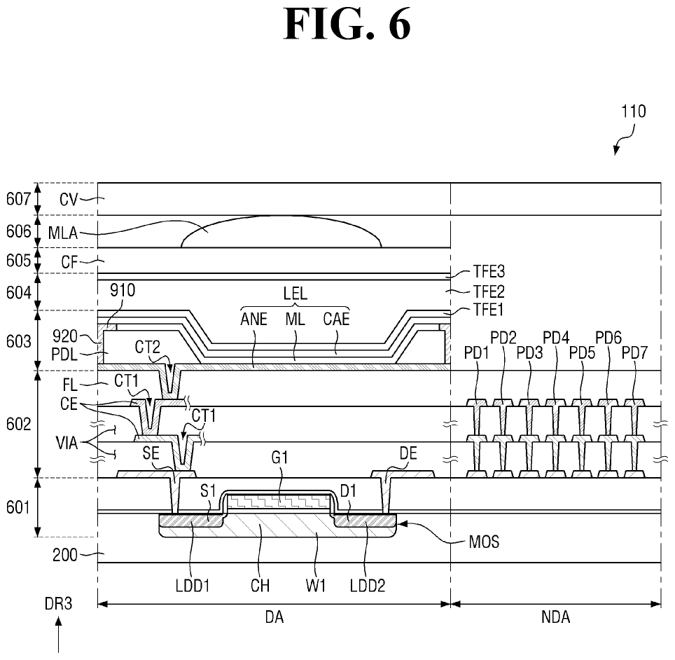

The main area MA may include a display area DA including pixels PX (see FIG. 3) displaying an image and a non-display area NDA disposed around the display area DA. The non-display area NDA may be an area other than the display area DA. The display area DA may emit light from multiple emission areas or multiple opening areas. For example, the display panel 110 may include pixel driving circuits PC (see FIG. 5) which include switching elements and light emitting elements LEL (see FIG. 6) which may be self-light emitting elements.

The light emitting elements LEL may include, but may not be limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

The non-display area NDA may be an area outside the display area DA. The non-display area NDA may be defined as an edge area of the main area MA of the display panel 110. The non-display area NDA may include fan-out lines extending from lines (e.g., gate lines, data lines, and emission control lines) of the display area DA and a display pad part (not illustrated) connecting the fan-out lines and a display driving circuit 210.

The sub-area SBA may extend from a side of the main area MA. The sub-area SBA may include a main pad part electrically connected to the circuit board 120. Optionally, the sub-area SBA may be omitted, and the main pad part may be disposed in the non-display area NDA.

The circuit board 120 may be attached onto the main pad part of the display panel 110 using an anisotropic conductive film (ACF). Lead lines of the circuit board 120 may be electrically connected to the main pad part of the display panel 110. The circuit board 120 may be a flexible printed circuit board, a printed circuit board, or a flexible film such as a chip on film.

The power supply part 130 may be disposed on the circuit board 120 to supply a power supply voltage to the display driving circuit 210 and the display panel 110. The power supply part 130 may generate driving voltages and supply the driving voltages to driving voltage lines. For example, the driving voltages may include a high potential voltage (a first driving voltage ELVDD of FIG. 5) and a low potential voltage (a second driving voltage ELVSS of FIG. 5) for driving the light emitting elements LEL.

FIG. 2 is a plan view of a display panel 110 according to an embodiment.

Referring to FIG. 2, the display panel 110 may be an organic light emitting diode on silicon (OLEDoS) panel using a semiconductor wafer substrate as a base substrate. For example, the display panel 110 may include a substrate 200, and the substrate 200 may be a semiconductor wafer substrate. In this disclosure, a substrate may be, but not necessarily, referred to as a ‘semiconductor substrate’, a ‘semiconductor wafer substrate’, or a ‘wafer’.

According to an embodiment, pixel driving circuits PC (see FIG. 5) and a display driving circuit 210 controlling the pixel driving circuits PC may be disposed on a front surface 201 of the substrate 200. The pixel driving circuits PC may be disposed to overlap light emitting elements LEL (see FIG. 6) of pixels PX (see FIG. 3) in the display area DA. The display driving circuit 210 may be disposed in the non-display area NDA and may drive the pixel driving circuits PC.

The pixel driving circuits PC (see FIG. 5) and the display driving circuit 210 may be formed in a driving element layer 601 (see FIG. 6) disposed on the front surface 201 of the substrate 200. The driving element layer 601 may include, for example, N-type metal oxide semiconductor field effect transistors (MOSFETs) and/or P-type MOSFETs. In this disclosure, the driving element layer 601 (see FIG. 6) may be, but not necessarily, referred to as a ‘MOSFET layer’, a ‘CMOS layer’, a ‘transistor layer’, or a ‘backplane layer’.

FIG. 3 is a schematic block diagram configuration of the display device 10 according to the embodiment.

Referring to FIG. 3, the display device 10 includes the display driving circuit 210 embedded in the display panel 110. The display driving circuit 210 may be formed in the driving element layer 601 disposed on the front surface of the substrate 200. The display driving circuit 210 may include a timing controller 310, a gate driver 320, an emission control driver 330, and a data driver 340, but the disclosure may not be limited thereto. Although not illustrated, the display driving circuit 210 may further include a memory (e.g., OTP), an interface circuit (e.g., I/F), an image processing circuit (e.g., logic), and/or a gamma processing circuit.

The display area DA of the display panel 110 may include multiple pixels PX arranged in a matrix form. Each of the pixels PX may be electrically connected to a first driving voltage line VDL, a second driving voltage line VSL, a gate line GL, an emission control line EML, and a data line DL.

The first driving voltage line VDL may supply a first driving voltage ELVDD (see FIG. 5) input from the power supply part 130 to the pixels PX. The second driving voltage line VSL may supply a second driving voltage ELVSS (see FIG. 5) input from the power supply part 130 to the pixels PX. The gate lines GL may supply gate signals GR and GW (see FIG. 5) input from the gate driver 320 to the pixels PX. The emission control lines EML may supply emission control signals EM input from the emission control driver 330 to the pixels PX. The data lines DL may supply analog data voltages input from the data driver 340 to the pixels PX.

The first driving voltage ELVDD may be a high potential voltage, and the second driving voltage ELVSS may be a low potential voltage. For example, the first driving voltage ELVDD may have a higher potential than the second driving voltage ELVSS.

One gate line GL illustrated in FIG. 3 may include a first gate line GWL and a second gate line GRL, but the disclosure may not be limited thereto.

Each of the pixels PX may include a light emitting element LEL (see FIG. 5) and may include multiple transistors and at least one capacitor as a pixel driving circuit PC (see FIG. 5) for driving the light emitting element LEL.

The timing controller 310 may receive a data signal DATA and timing signals from the circuit board 120. The timing controller 310 may generate a data control signal DCS based on the timing signals, and control the operation timing of the data driver 340 using the data control signal DCS. The timing controller 310 may generate a gate control signal GCS based on the timing signals, and control the operation timing of the gate driver 320 using the gate control signal GCS. The timing controller 310 may generate an emission control signal ECS based on the timing signals, and control the operation timing of the emission control driver 330 based on the emission control signal ECS.

The data driver 340 may convert the data signal DATA into analog data voltages and supply the analog data voltages to the pixels PX through the data lines DL. Gate signals of the gate driver 320 may select pixels PX to which the data voltages may be supplied, and the selected pixels PX may receive the data voltages through the data lines DL.

The power supply part 130 may be disposed on the circuit board 120 to supply a power supply voltage to the display driving circuit 210 and the display panel 110. The power supply part 130 may generate a driving voltage and may supply the driving voltage to a driving voltage line VDL or VSL. The power supply part 130 may generate a common voltage and may supply the common voltage to a second electrode (e.g., a second electrode CAE of FIG. 6) commonly electrically connected to the light emitting elements LEL of the pixels PX.

The gate driver 320 may supply the gate signals GR and GW (see FIG. 5) to the pixels PX through the gate lines GL.

The emission control driver 330 may supply the emission control signals EM (see FIG. 5) to the pixels PX through the emission control lines EML.

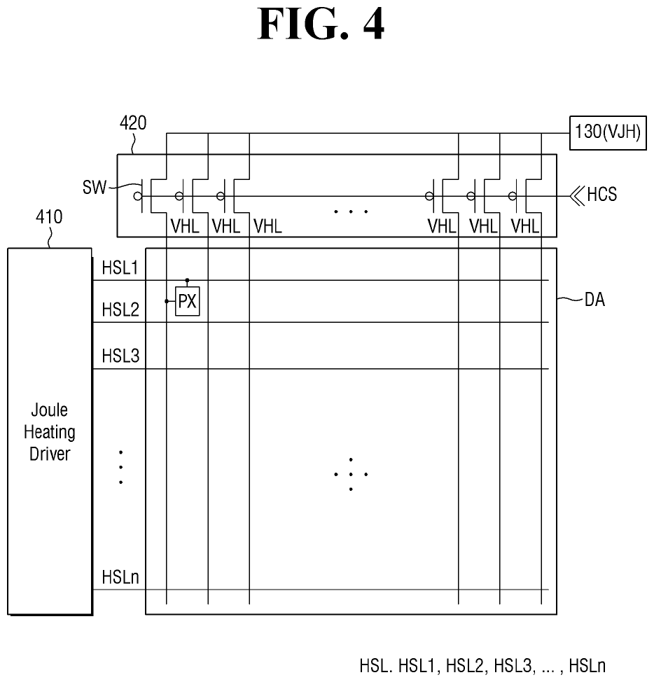

FIG. 4 is a schematic block diagram configuration of a joule heating driver 410 and a switching circuit 420 according to an embodiment.

Referring to FIG. 4, the display panel 110 of the display device 10 according to the embodiment further includes the joule heating driver 410 and the switching circuit 420. The joule heating driver 410 may be disposed in the non-display area NDA and may be electrically connected to multiple heating scan wirings HSL1 to HSLn (or just HSL) disposed in the display area DA. The switching circuit 420 may be disposed in the non-display area NDA and may be electrically connected to multiple heating voltage supply wirings VHL disposed in the display area DA. In the display area DA, the heating voltage supply wirings VHL and the heating scan wirings HSL may intersect each other.

The joule heating driver 410 may sequentially output a heating scan signal HS (see FIG. 5) to the heating scan wirings HSL. For example, the joule heating driver 410 may output the heating scan signal HS to a first heating scan wiring HSL1 in a first period, and may output the heating scan signal HS to a second heating scan wiring HSL2 in a second period after the first period. The joule heating driver 410 may output the heating scan signal HS to a third heating scan wiring HSL3 in a third period after the second period. The heating scan signal HS output from the joule heating driver 410 serves to select pixels PX to which a joule heating voltage VJH may be supplied. The pixels PX receiving the heating scan signal HS may receive the joule heating voltage VJH through the heating voltage supply wirings VHL.

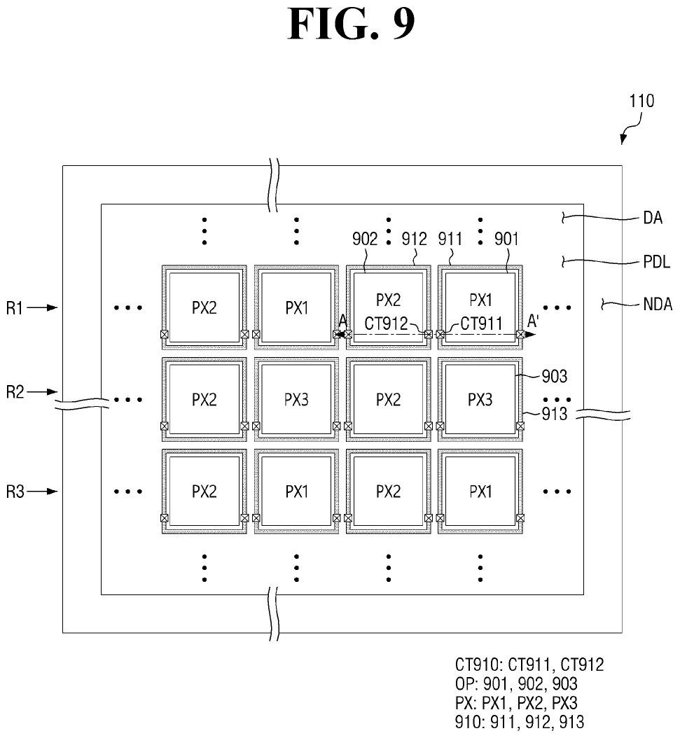

According to an embodiment, the joule heating driver 410 may set a scan on time (SOT) of each heating scan signal HS to be longer than an SOT of a gate signal output from the gate driver 320. The joule heating driver 410 may set the SOT of each heating scan signal HS to be relatively longer than the SOT of the gate signals GR and GW (see FIG. 5) in order to secure a sufficient joule heating time for heating a heating wiring 910 (see FIG. 9). For example, pixels PX selected by a heating scan signal HS may receive the joule heating voltage VJH during the SOT of the heating scan signal HS. The SOT of the heating scan signal HS may be a time during which the joule heating voltage VJH may be supplied to the pixels PX. The joule heating voltage VJH supplied to each pixel PX may be transmitted to the heating wiring 910 through a first electrode ANE (see FIG. 6), and the heating wiring 910 may be heated by the transmitted joule heating voltage VJH. Therefore, as the SOT of the heating scan signal HS increases, the time during which the heating wiring 910 may be heated also increases.

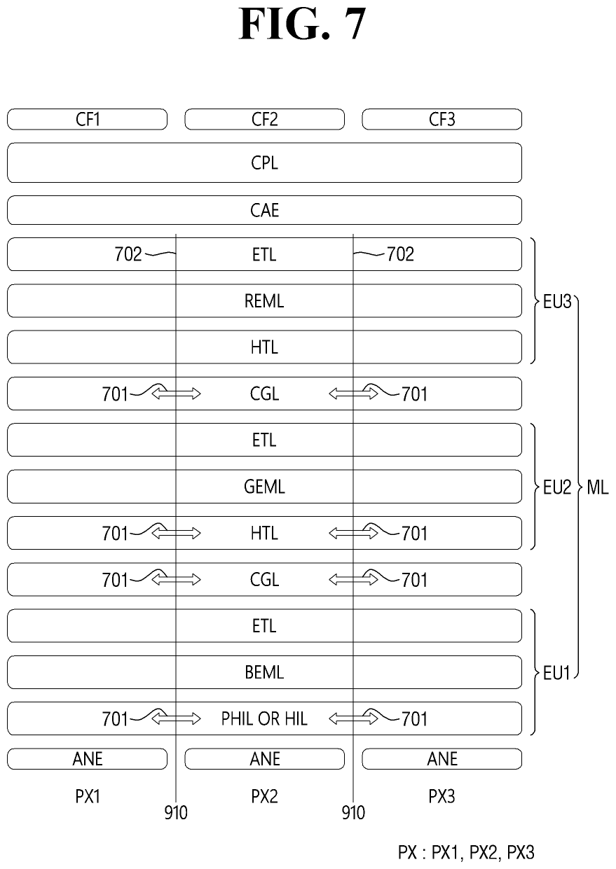

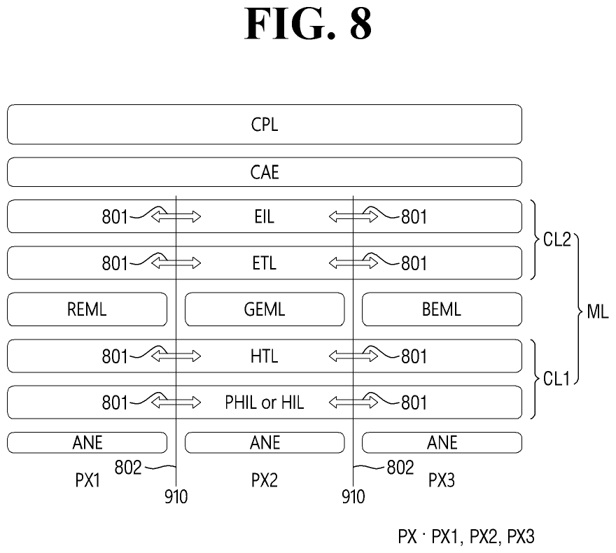

The heating wiring 910 may be heated to electrically disconnect an intermediate layer ML (see FIG. 6) of a light emitting element LEL, which may be disposed around the heating wiring 910 or on the heating wiring 910, during a process of manufacturing the display panel 110. According to an embodiment of the disclosure, the intermediate layer ML may be electrically disconnected in some areas between neighboring pixels PX to prevent leakage current through the intermediate layer ML and prevent color crosstalk. The electrical disconnection of the intermediate layer ML will be described in detail later with reference to FIGS. 7 and 8.

The switching circuit 420 may supply the joule heating voltage VJH to the heating voltage supply wirings VHL in synchronization with the timing at which the joule heating driver 410 may output the heating scan signal HS. The switching circuit 420 may include multiple switching transistors SW electrically connected one-to-one to the heating voltage supply wirings VHL. The switching transistors SW may be turned on in response to a heating control signal HCS. In case of being turned on, the switching transistors SW may supply the joule heating voltage VJH to the heating voltage supply wirings VHL. Here, the heating control signal HCS may be synchronized with the heating scan signal HS output by the joule heating driver 410.

According to an embodiment, each switching transistor SW may include a gate electrically connected to a supply wiring of the heating control signal HCS, a source (e.g., a first terminal) electrically connected to the power supply part 130 that generates the joule heating voltage VJH, and a drain (e.g., a second terminal) electrically connected to a heating voltage supply wiring VHL. Each switching transistor SW may be turned on in response to the heating control signal HCS input through the gate and, in case of being turned on, may supply the joule heating voltage VJH input from the source to the heating voltage supply wiring VHL through the drain. Although the switching transistors SW may be P-type MOSFETs in the illustrated example, the disclosure may not be limited thereto.

Each of the pixels PX disposed in the display area DA may be electrically connected to a heating scan wiring HSL and a heating voltage supply wiring VHL. Each pixel PX may receive the heating scan signal HS output from the joule heating driver 410 through the heating scan wiring HSL. Each pixel PX may receive the joule heating voltage VJH through the heating voltage supply wiring VHL in synchronization with the timing at which the heating scan signal HS is received. The joule heating voltage VJH input to each pixel PX may be transmitted to a first electrode (e.g., ANE of FIG. 6) of a light emitting element LEL, and the first electrode ANE may be electrically connected to a heating wiring 910 through a connection electrode 920 (see FIG. 6). Therefore, the joule heating voltage VJH supplied to the first electrode ANE may be transmitted to the heating wiring 910 via the connection electrode 920. The heating wiring 910 may be heated by the transmitted joule heating voltage VJH, thereby electrically disconnecting the intermediate layer ML disposed around the heating wiring 910. The resistance of the heating wiring 910 may be greater than the resistance of the first electrode ANE and the resistance of the connection electrode 920. Accordingly, in case that the joule heating voltage VJH is applied, the temperature of the heating wiring 910 may be higher than the temperature of each of the connection electrode 920 and the first electrode ANE.

FIG. 5 is a schematic diagram of an equivalent circuit of a pixel PX of the display device 10 according to the embodiment.

Referring to FIG. 5, the pixel PX may include a light emitting element LEL (e.g., an organic light emitting diode) and a pixel driving circuit PC electrically connected to the light emitting element LEL. The pixel driving circuit PC may include first through fifth transistors T1 through T5, a first capacitor C1, and a second capacitor C2, but the disclosure may not be limited thereto. The first through fifth transistors T1 through T5 may be implemented as N-type MOSFETs and/or P-type MOSFETs. Although the first through fifth transistors Tl through T5 may be illustrated as P-type MOSFETs in FIG. 5, the disclosure may not be limited thereto.

The first transistor T1 may be a driving transistor in which the magnitude of a source-drain current may be determined according to a gate-source voltage. Each of the second through fourth transistors T2 through T4 may be a switching transistor that may be turned on/off according to a gate-source voltage or substantially a gate voltage. The fifth transistor T5 may be a heating transistor for supplying a joule heating voltage VJH to a first electrode ANE of the light emitting element LEL.

The first transistor T1 may include a gate electrically connected to a first node N1, a source electrically connected to a second node N2, and a drain electrically connected to a third node N3. The first transistor T1 may be turned on or off based on a voltage level of the first node N1. The turned-on first transistor T1 may connect the second node N2 and the third node N3. The second node N2 may be a node electrically connected to a drain of the third transistor T3 and supplied with a first driving voltage ELVDD in case that the third transistor T3 is turned on in response to an emission control signal EM. The third node N3 may be a node to which the first electrode ANE (see FIG. 6) of the light emitting element LEL and a source of the fourth transistor T4 may be connected to. The third node N3 may be a node to which a second driving voltage ELVSS may be supplied in case that the fourth transistor T4 is turned on in response to a second gate signal GR.

The second transistor T2 may include a gate electrically connected to a first gate line GWL, a source electrically connected to a data line, and a drain electrically connected to the first node N1. The second transistor T2 may be turned on in response to a first gate signal GW supplied from the first gate line GWL. The turned-on second transistor T2 may supply a data signal Vdat supplied from the data line to the first node N1.

The third transistor T3 may include a gate electrically connected to an emission control line EML, a source electrically connected to a first driving voltage line VDL to which the first driving voltage ELVDD may be supplied, and the drain electrically connected to the second node N2. The third transistor T3 may be turned on in response to the emission control signal EM supplied from the emission control line EML. The turned-on third transistor T3 may supply the first driving voltage ELVDD to the second node N2.

The fourth transistor T4 may include a gate electrically connected to a second gate line GRL, a drain electrically connected to the second driving voltage line VSL to which the second driving voltage ELVSS may be supplied, and the source electrically connected to the third node N3. The fourth transistor T4 may be turned on in response to the second gate signal GR supplied from the second gate line GRL. The turned-on fourth transistor T4 may supply the second driving voltage ELVSS to the third node N3.

The fifth transistor T5 may include a gate electrically connected to a heating scan wiring HSL, a source electrically connected to a heating voltage supply wiring VHL, and a drain electrically connected to the third node N3. The fifth transistor T5 may be turned on in response to the heating scan signal HS supplied from the heating scan wiring HSL. The turned-on fifth transistor T5 may supply the joule heating voltage VJH to the third node N3.

The first capacitor CI may be disposed between the first node NI and the second node N2. The second capacitor C2 may be disposed between the first node NI and the third node N3. The first and second capacitors C1 and C2 serve to store the data signal Vdat input through the second transistor T2.

The light emitting element LEL may include the first electrode (e.g., the first electrode ANE of FIG. 6), a second electrode (e.g., a second electrode CAE of FIG. 6) facing the first electrode, and an intermediate layer ML disposed between the first electrode ANE and the second electrode CAE. The intermediate layer ML may include an organic light emitting layer. The second electrode CAE may receive the second driving voltage ELVSS. The second electrode CAE may be electrically connected to the second driving voltage line VSL that transmits the second driving voltage ELVSS. The second electrode CAE may be commonly electrically connected to multiple pixels PX.

FIG. 6 is a schematic cross-sectional view of a portion of the display panel 110 of the display device 10 according to the embodiment. For example, FIG. 6 schematically illustrates the stacked structure of each of the non-display area NDA and the display area DA of the display panel 110 according to the embodiment.

In the description with reference to FIG. 6, the expression “on” may mean a third direction DR3 in which a front surface of a substrate 200 faces. The front surface of the substrate 200 may refer to a direction in which each light emitting element LEL disposed in the display area DA emits light for displaying an image.

Referring to FIG. 6, the display panel 110 according to the embodiment may include the substrate 200, and the substrate 200 may be a semiconductor wafer substrate.

A driving element layer 601 including a display driving circuit 210 and a pixel driving circuit PC, at least one wiring layer 602, a light emitting element layer 603 including a light emitting element LEL, an encapsulation layer 604 covering the light emitting element LEL, a color filter layer 605 including a color filter CF, a light control layer 606 including a refractive layer MLA, and a cover layer 607 including a cover member CV may be sequentially stacked on each other on the front surface of the substrate 200. At least some of the light emitting element layer 603, the encapsulation layer 604, the color filter layer 605, the light control layer 606, and the cover layer 607 may not be disposed in the non-display area NDA.

The substrate 200 may be a silicon substrate, a germanium substrate, or a silicon-germanium substrate. The substrate 200 may be a substrate doped with first-type impurities.

The driving element layer 601 including an N-type MOSFET and/or a P-type MOSFET may be disposed on the substrate 200. The first-type impurities may be P-type impurities, and second-type impurities may be N-type impurities. The first-type impurities may be N-type impurities, and the second-type impurities may be P-type impurities.

In this disclosure, an N-type MOSFET MOS included in the driving element layer 601 will be described as an example. The N-type MOSFET MOS may include a well region W1 doped with N-type impurities in a substrate doped with P-type impurities.

The well region W1 may include a first low-concentration impurity region LDD1 and a second low-concentration impurity region LDD2 having a relatively lower impurity concentration than other portions. The first low-concentration impurity region LDD1 may define a source region S1, and the second low-concentration impurity region LDD2 may define a drain region D1. A source electrode SE of the MOSFET MOS may be electrically connected to the source region S1, and a drain electrode DE of the MOSFET MOS may be electrically connected to the drain region D1.

A channel CH may be defined between the first low-concentration impurity region LDD1 and the second low-concentration impurity region LDD2 to overlap a gate G1. An oxide layer (not illustrated) which may be an insulating layer may be disposed between the gate G1 and the well region W1.

MOSFETs MOS constitute the display driving circuit 210 (see FIG. 2), and the display driving circuit 210 may be disposed in the non-display area NDA of the display panel 110. MOSFETs MOS constitute transistors (T1 through T5 of FIG. 5) included in a pixel driving circuit PC, and the pixel driving circuit PC may be disposed in the display area DA of the display panel 110. That is, each pixel driving circuit PC may be a circuit including a combination of MOSFETs MOS disposed in the driving element layer 601 to correspond to the display area DA. The display driving circuit 210 may be a circuit including a combination of MOSFETs MOS disposed in the driving element layer 601 to correspond to the non-display area NDA. For case of description, FIG. 6 illustrates any one MOSFET MOS of the pixel driving circuit PC disposed in the display area DA of the display panel 110 as an example.

At least one wiring layer 602 may be disposed on the driving element layer 601. The at least one wiring layer 602 may include insulating layers VIA sequentially stacked on the driving element layer 601, and connection electrodes CE and wirings (not illustrated) electrically connected to the MOSFETs MOS through contact holes CT1 at least partially penetrating the insulating layers VIA. The wiring layer 602 may include the connection electrodes CE and the connection wirings for connecting the MOSFETs MOS of the driving element layer 601 to each other and the insulating layers VIA for insulating them from each other. The wiring layer 602 may include multiple signal wirings for driving the display panel 110 and multiple power supply wirings.

The connection electrodes CE illustrated in FIG. 6 connect a MOSFET MOS corresponding to a pixel driving circuit PC among multiple MOSFETs MOS disposed in the driving element layer 601 to a light emitting element LEL disposed on the wiring layer 602 in a vertical direction. Here, the vertical direction means a normal direction DR3 of the display panel 110.

Wirings (not illustrated) disposed in the wiring layer 602 include lines (e.g., GL, DL and EML of FIG. 3 and HSL of FIG. 4) electrically connected to the pixel driving circuit PC. The wirings disposed in the wiring layer 602 may further include fan-out lines (not illustrated) extending from the lines GL, DL, EML and HSL electrically connected to the pixel driving circuit PC and disposed in the non-display area NDA.

The wiring layer 602 may include pad electrodes PD1 through PD7 disposed to correspond to the non-display area NDA. The pad electrodes PD1 through PD7 include a first gate pad PD1 to which a first gate line GWL may be connected, a second gate pad PD2 to which a second gate line GRL may be connected, a joule heating pad PD3 to which a joule heating voltage VJH may be supplied, an emission pad PD4 to which an emission control line EML may be connected, a data pad PD5 to which a data line DL may be connected, a first driving voltage pad PD6 to which a first driving voltage line VDL may be connected, and a second driving voltage pad PD7 to which a second driving voltage line VSL may be connected. However, the pad electrodes PD1 through PD7 illustrated in FIG. 6 may be only an example, and the disclosure is not limited thereto.

A planarization layer FL including an organic layer may be disposed on an uppermost layer among the insulating layers VIA included in the wiring layer 602.

A pixel defining layer PDL defining multiple pixels PX and the light emitting element layer 603 including a light emitting element LEL may be disposed on the wiring layer 602. The light emitting element LEL may include a first electrode ANE electrically connected to the MOSFET MOS included in the pixel driving circuit PC through a contact hole CT2 and the connection electrodes CE, an intermediate layer ML disposed on the first electrode ANE, and a second electrode CAE disposed on the intermediate layer ML. The pixel defining layer PDL may include openings OP (see FIG. 9) corresponding to the pixels PX, respectively, and a portion of the first electrode ANE may be exposed in each opening OP.

The intermediate layer ML may include a hole injection layer HIL, a hole transport layer HTL, a light emitting layer, an electron transport layer ETL, and an electron injection layer EIL, but the disclosure may not be limited thereto. For example, the light emitting element LEL may be an RGB-type light emitting element LEL that emits light of a first color (e.g., red light) in a first pixel PX1 (e.g., a red pixel), emits light of a second color (e.g., green light) in a second pixel PX2 (e.g., a green pixel), and emits light of a third color (e.g., blue light) in a third pixel PX3 (e.g., a blue pixel). The light emitting element LEL may be a white OLED (WOLED)-type light emitting element LEL that emits white light in all of the first pixel PX1 (e.g., the red pixel), the second pixel PX2 (e.g., the green pixel), and the third pixel PX3 (e.g., the blue pixel).

A stacked structure of organic materials included in the intermediate layer ML may be different depending on whether the light emitting element LEL may be of the RGB type or the WOLED type, but the disclosure may not be limited thereto.

A heating wiring 910 may be disposed on the pixel defining layer PDL. The heating wiring 910 causes the intermediate layer ML of the light emitting element LEL to be electrically disconnected between adjacent pixels PX during a process. The electrical disconnection of the intermediate layer ML occurs in a process of applying the joule heating voltage VJH to the heating wiring 910. The process of applying the joule heating voltage VJH to the heating wiring 910 may be performed after the intermediate layer ML is deposited. As will be described later, the process of applying the joule heating voltage VJH to the heating wiring 910 may be performed before a process of depositing the second electrode CAE or after the process of depositing the second electrode CAE.

According to an embodiment, the heating wiring 910 may be electrically connected to the first electrode ANE through a connection electrode 920 vertically penetrating the pixel defining layer PDL. The heating wiring 910 may be configured to receive the joule heating voltage VJH through the first electrode ANE and the connection electrode 920 and generate heat in response to the received joule heating voltage VJH. The temperature of the heating wiring 910 may be raised to a high temperature of about 400° C. or higher by the received joule heating voltage VJH, and the intermediate layer ML deposited on and around the heating wiring 910 may be removed by the high temperature.

In an embodiment, the intermediate layer ML of the light emitting element LEL may be electrically disconnected between adjacent pixels PX, thereby preventing leakage current between the adjacent pixels PX and preventing color crosstalk. The color crosstalk refers to a phenomenon in which, for example, a red pixel (e.g., the first pixel PX1) adjacent to a blue pixel (e.g., the third pixel PX3) may be unintentionally turned on while the blue pixel may be emitting blue light. The color crosstalk occurs due to the leakage current and may occur in case that the blue pixel and the red pixel having a large difference in voltage that drives the pixels are adjacent to each other. For example, the leakage current may be a phenomenon in which while a driving current may be being supplied to the light emitting element LEL of the blue pixel in order to turn on the blue pixel, a portion of the driving current may be transmitted to the red pixel (e.g., the first pixel PX1) through at least some conductive layers of the intermediate layer ML. In case that the leakage current is generated, the red pixel may be unintentionally turned on while the blue pixel is being turned on.

The encapsulation layer 604 including at least one organic encapsulation layer and at least one inorganic encapsulation layer may be disposed on the light emitting element layer 603. For example, the encapsulation layer 604 may include a first encapsulation inorganic layer TFE1, an encapsulation organic layer TFE2, and a second encapsulation inorganic layer TFE3, but the disclosure may not be limited thereto.

The color filter layer 605 including the color filter CF may be disposed on the encapsulation layer 604. The color filter CF may include a first color filter CF1 that transmits red light, a second color filter CF2 that transmits green light, or a third color filter CF3 that transmits blue light, but the disclosure may not be limited thereto. The color filter layer 605 may be provided in case that the light emitting element LEL of the light emitting element layer 603 is a WOLED-type light emitting element LEL. If the light emitting element LEL of the light emitting element layer 603 is an RGB-type light emitting element LEL that emits (e.g., directly emits) red light, green light or blue light, the color filter layer 605 may be omitted.

The light control layer 606 including the refractive layer MLA may be disposed on the color filter layer 605. The refractive layer MLA may refract light emitted from the light emitting element layer 603 and incident in the normal direction DR3 of the display panel 110. The refractive layer MLA may include a micro-lens array.

The cover layer 607 serving as a cover of the display panel 110 may be disposed on the light control layer 606. The cover layer 607 may include the cover member CV made of glass, but the disclosure may not be limited thereto. The cover layer 607 may include, for example, a protective film.

FIG. 7 is a cross-sectional view schematically illustrating the stacked structure of a light emitting element LEL according to an embodiment. For example, FIG. 7 illustrates the stacked structure of the intermediate layer ML in case that the light emitting element LEL of the light emitting element layer 603 may be a WOLED-type light emitting element LEL.

Referring to FIG. 7, a display panel 110 according to an embodiment may include multiple pixels PX including a first pixel PX1 for displaying a first color (e.g., red), a second pixel PX2 for displaying a second color (e.g., green), and a third pixel PX3 for displaying a third color (e.g., blue).

A light emitting element LEL disposed in each of the first pixel PX1, the second pixel PX2, and the third pixel PX3 may emit white light. The display panel 110 may display the first color, the second color, and the third color using color filters. For example, white light emitted from the first pixel PX1 may pass through a first color filter CFI to display the first color, white light emitted from the second pixel PX2 may pass through a second color filter CF2 to display the second color, and white light emitted from the third pixel PX3 may pass through a third color filter CF3 to display the third color.

A first electrode ANE (e.g., a pixel electrode or an anode) may be disposed in each of the first pixel PX1, the second pixel PX2, and the third pixel PX3. An intermediate layer ML and a second electrode CAE may be disposed on the first electrode ANE of each of the first pixel PX1, the second pixel PX2, and the third pixel PX3.

The intermediate layer ML and the second electrode CAE may be common layers commonly stacked in the first pixel PX1, the second pixel PX2 and the third pixel PX3 and may be continuous in at least some areas between the pixels PX.

The intermediate layer ML may include a first emission part EU1, a charge generation layer CGL, a second emission part EU2, a charge generation layer CGL, and a third emission part EU3 sequentially stacked on each other on the first electrode ANE of each of the first pixel PX1, the second pixel PX2 and the third pixel PX3, but the disclosure may not be necessarily limited thereto. The stacking order and structure of the intermediate layer ML may be variously changed.

The first emission part EU1 may include a hole injection layer HIL or a P-doped layer PHIL doped with a P-type semiconductor, a blue light emitting layer BEML, and an electron transport layer ETL. The second emission part EU2 may include a hole transport layer HTL, a green light emitting layer GEML, and an electron transport layer ETL. The third emission part EU3 may include a hole transport layer HTL, a red light emitting layer REML, and an electron transport layer ETL.

The charge generation layer CGL may be disposed between the first emission part EU1 and the second emission part EU2. The charge generation layer CGL may be disposed between the second emission part EU2 and the third emission part EU3. The charge generation layer CGL may include a negative charge generation layer and a positive charge generation layer.

The second electrode CAE may be disposed on the third emission part EU3. The second electrode CAE may be a common layer commonly stacked in the first pixel PX1, the second pixel PX2 and the third pixel PX3 and may be continuous in at least some areas between the pixels PX.

A capping layer CPL may be disposed on the second electrode CAE. Although not illustrated, the encapsulation layer 604 (see FIG. 6) may be disposed on the capping layer CPL, and the first color filter CF1, the second color filter CF2 and the third color filter CF3 may be disposed on the encapsulation layer 604. The capping layer CPL may improve luminous efficiency through the principle of constructive interference.

In the display panel 110 according to the embodiment, since the intermediate layer ML disposed between the first electrode ANE and the second electrode CAE may be commonly stacked in the first pixel PX1, the second pixel PX2 and the third pixels PX3 and may be continuous in at least some areas between the pixels PX, a leakage current may be generated. The leakage current may flow between adjacent pixels PX through at least some conductive layers included in the intermediate layer ML, as indicated by arrows 701 in FIG. 7.

The display panel 110 according to the embodiment may include a heating wiring 910 in an area between multiple pixels PX to prevent leakage current. For example, the heating wiring 910 may be disposed on the pixel defining layer PDL between neighboring pixels PX. The heating wiring 910 disposed between neighboring pixels PX may be driven before or after the process of depositing the second electrode CAE. In case that the heating wiring 910 is driven, high-temperature heat may be generated, and the generated high-temperature heat may cause at least some conductive layers included in the intermediate layer ML to become electrically disconnected. In the disclosure, since at least some conductive layers included in the intermediate layer ML may be electrically disconnected around the heating wiring 910 between neighboring pixels PX as indicated by solid lines 702 in FIG. 7, leakage current and color crosstalk may be prevented.

FIG. 8 is a cross-sectional view schematically illustrating the stacked structure of a light emitting element LEL according to an embodiment. For example, FIG. 8 illustrates the stacked structure of an intermediate layer ML in case that the light emitting element LEL of the light emitting element layer 603 may be an RGB-type light emitting element LEL that emits (e.g., directly emits) red light in a first pixel PX1, green light in a second pixel PX2, and blue light in a third pixel PX3.

Referring to FIG. 8, a display panel 110 according to an embodiment may include multiple pixels PX including a first pixel PX1 for displaying a first color (e.g., red), a second pixel PX2 for displaying a second color (e.g., green), and a third pixel PX3 for displaying a third color (e.g., blue).

Each of the first pixel PX1, the second pixel PX2, and the third pixel PX3 may emit (e.g., directly emit) light of a designated color. For example, a light emitting element LEL in the first pixel PX1 may include a red light emitting layer REML to emit red light from a first emission area, a light emitting element LEL in the second pixel PX2 may include a green light emitting layer GEML to emit green light from a second emission area, and a light emitting element LEL in the third pixel PX3 may include a blue light emitting layer BEML to emit blue light from a third emission area. Here, the first emission area may be an area where a first electrode ANE provided in the first pixel PX1 may be covered by the intermediate layer ML, the second emission area may be an area where a first electrode ANE provided in the second pixel PX2 may be covered by the intermediate layer ML, and a third emission area may be an area where a first electrode ANE provided in the third pixel PX3 may be covered by the intermediate layer ML.

The first electrode ANE (e.g., a pixel electrode or an anode) may be disposed in each of the first pixel PX1, the second pixel PX2, and the third pixel PX3. The intermediate layer ML and a second electrode CAE may be disposed on the first electrode ANE of each of the first pixel PX1, the second pixel PX2, and the third pixel PX3. The intermediate layer ML may include a first common layer CL1 (e.g., a lower common layer), a light emitting layer and a second common layer CL2 (e.g., an upper common layer), and the second electrode CAE may be disposed on the intermediate layer ML.

The first common layer CL1, the second common layer CL2, and the second electrode CAE may be common layers commonly stacked in the first pixel PX1, the second pixel PX2 and the third pixel PX3 and may be continuous in at least some areas between the pixels PX. On the other hand, different light emitting layers REML, GEML and BEML may be respectively disposed in the first pixel PX1, the second pixel PX2, and the third pixel PX3 between the first common layer CL1 and the second common layer CL2. For example, the red light emitting layer REML may be disposed in the first pixel PX1, the green light emitting layer GEML may be disposed in the second pixel PX2, and the blue light emitting layer BEML may be disposed in the third pixel PX3. The light emitting layers REML, GEML and BEML may be discrete and electrically disconnected at the boundary of each pixel PX.

The first common layer CL1 may be a layer disposed under the light emitting layers REML, GEML and BEML and may include a hole injection layer HIL or a P-doped hole injection layer PHIL doped with a P-type semiconductor and a hole transport layer HTL. However, the disclosure may not be limited thereto. For example, the first common layer CL1 may include at least one hole injection layer HIL and at least one hole transport layer HTL.

The second common layer CL2 may be a layer disposed on the light emitting layers REML, GEML and BEML and may include an electron transport layer ETL and an electron injection layer EIL. However, the disclosure may not be limited thereto. For example, the second common layer CL2 may include at least one electron transport layer ETL and at least one electron injection layer EIL.

A capping layer CPL may be disposed on the second electrode CAE. The capping layer CPL may improve luminous efficiency through the principle of constructive interference.

Unlike the embodiment of FIG. 7, the embodiment of FIG. 8 does not include color filters.

As in the embodiment of FIG. 7, in the display panel 110 according to the embodiment illustrated in FIG. 8, the first common layer CL1 and the second common layer CL2 disposed between the first electrode ANE and the second electrode CAE may be commonly stacked in the first pixel PX1, the second pixel PX2 and the third pixel PX3 and may be continuous in at least some areas between the pixels PX. Therefore, a leakage current may be generated through the first common layer CL1 and the second common layer CL2. The leakage current may flow between adjacent pixels PX through at least some conductive layers included in the first common layer CL1 and the second common layer CL2, as indicated by arrows 801 in FIG. 8.

The display panel 110 according to the embodiment of the disclosure may include a heating wiring 910 in an area between neighboring pixels PX to prevent leakage current by causing at least some conductive layers included in the intermediate layer ML to become disjoined and electrically disconnected from each other using the heating wiring 910. In the disclosure, since at least some conductive layers included in the intermediate layer ML may become electrically disconnected around the heating wiring 910 between neighboring pixels PX as indicated by solid lines 802 in FIG. 8, leakage current and color crosstalk may be prevented. In this disclosure, at least some conductive layers of the intermediate layer ML which may be electrically disconnected around the heating wiring 910 may include at least one of the hole injection layer HIL, the hole transport layer HTL, the electron transport layer ETL, and the electron injection layer EIL.

FIG. 9 is a schematic plan view of a portion of a display area DA of a display panel 110 according to an embodiment. For example, FIG. 9 may be a plan view illustrating a portion of the display panel 110 viewed in a normal direction perpendicular to an upper surface of the display panel 110 (or a substrate 200).

Referring to FIG. 9, the display panel 110 may include multiple pixels PX including first pixels PX1, second pixels PX2, and third pixels PX3. The pixels PX may be arranged in a matrix form in the display area DA of the display panel 110. For example, the first pixels PX1 and the second pixels PX2 may be alternately disposed in each of odd-numbered rows R1 and R3 in which multiple pixels PX may be disposed, and the second pixels PX2 and the third pixels PX3 may be alternately disposed in each even-numbered row R2. The first pixels PX1 disposed in the odd-numbered rows R1 and R3 and the third pixels PX3 disposed in the even-numbered row R2 may be disposed adjacent to each other in a column direction (i.e., a vertical direction), and the second pixels PX2 disposed in the odd-numbered rows R1 and R3 and the second pixels PX2 disposed in the even-numbered row R2 may be disposed adjacent to each other in the column direction (i.e., the vertical direction). At least some of the first pixels PX1, the second pixels PX2, and the third pixels PX3 illustrated in FIG. 9 may be replaced with fourth pixels (not illustrated) displaying white light. The arrangement of the pixels PX illustrated in FIG. 9 may be only an example, and the disclosure may not be limited thereto.

In FIG. 9, solid lines (e.g., 901, 902 and 903 in FIG. 9) indicating areas of the first pixels PX1, the second pixels PX2 and the third pixels PX3 indicate openings OP of a pixel defining layer PDL which may be disposed in the first pixels PX1, the second pixels PX2, and the third pixels PX3, respectively. For example, the first pixels PX1 may be defined in first openings 901 of the pixel defining layer PDL, the second pixels PX2 may be defined in second openings 902 of the pixel defining layer PDL, and the third pixels PX3 may be defined in third openings 903 of the pixel defining layer PDL. In FIG. 9, an area outside the solid lines (e.g., 901, 902 and 903 in FIG. 9) may be interpreted as an area where the pixel defining layer PDL may be substantially disposed.

According to an embodiment, a heating wiring 910 may be disposed between neighboring pixels PX. The heating wiring 910 may be disposed on the pixel defining layer PDL and may surround each opening OP of the pixel defining layer PDL. For example, a first heating wiring 911 may be disposed around the first opening 901 corresponding to each of the first pixels PX1 and may surround the first opening 901. A second heating wiring 912 may be disposed around the second opening 902 corresponding to each of the second pixels PX2 and may surround the second opening 902. Similarly, a third heating wiring 913 may surround the third opening 903 corresponding to each of the third pixels PX3.

According to an embodiment, the heating wirings 910 may be driven independently of each other. The heating wirings 910 may be individually provided around the openings OP, respectively, and may be electrically connected to first electrodes ANE through contact holes CT910 penetrating the pixel defining layer PDL. For example, the first heating wirings 911 surrounding the first openings 901 may be electrically connected to the first electrodes ANE of the first pixels PX1 through first contact holes CT911. The second heating wirings 912 surrounding the second openings 902 may be electrically connected to the first electrode ANE of the second pixels PX2 through second contact holes CT912. The contact holes CT910 may be disposed in an area surrounding each opening OP, and the positions of the contact holes CT910 may not be limited to the illustrated example.

Although not illustrated, each heating wiring 910 may form a current path by being electrically connected to ground through a dummy contact hole (not illustrated). For example, a joule heating voltage VJH input to each heating wiring 910 through heating voltage supply wiring VHL may form a current path flowing to the outside through the dummy contact hole. To this end, the disclosure may further include the dummy contact hole (not illustrated) and a ground connection electrode (not illustrated) connecting a ground wiring (not illustrated) and the heating wiring 910 through the dummy contact hole.

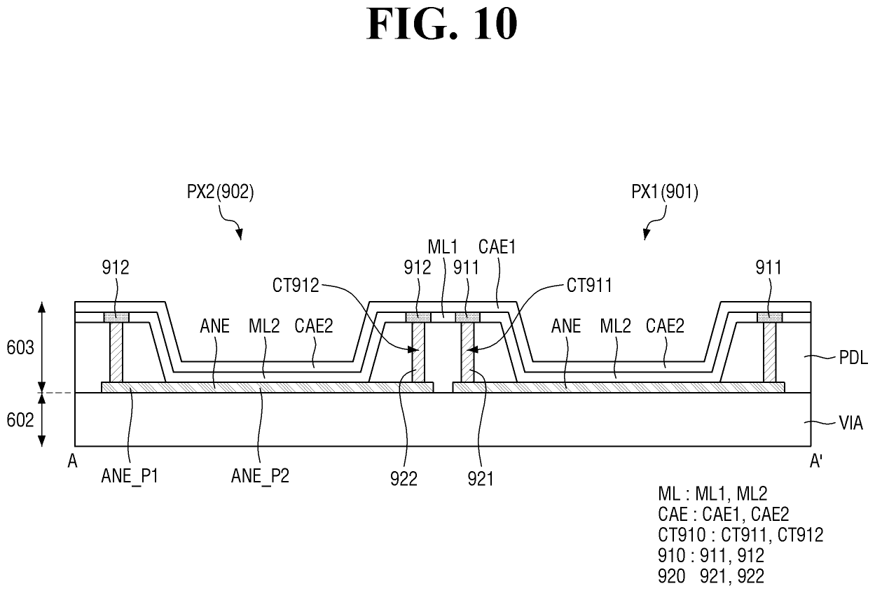

FIG. 10 is a cross-sectional view schematically illustrating the cross-sectional structure of neighboring pixels (e.g., PX1 and PX2) illustrated in FIG. 9. For example, FIG. 10 may be a cross-sectional view of a light emitting element layer 603 of the display panel 110 taken along line A-A′ of FIG. 9.

Referring to FIG. 10, the pixel defining layer PDL may be disposed on a wiring layer 602 to separate neighboring pixels (e.g., PX1 and PX2). In the illustrated example, the pixel defining layer PDL may separate a first pixel PX1 from a second pixel PX2 neighboring each other. For example, a first electrode ANE of the first pixel PX1 may be disposed in a first opening 901 of the pixel defining layer PDL, and a first electrode ANE of the second pixel PX2 may be disposed in a second opening 902. The pixel defining layer PDL may be disposed between the first opening 901 and the second opening 902.

An intermediate layer ML may be disposed on the first electrodes ANE in the openings OP (901 and 902) of the first pixel PX1 and the second pixel PX2. The intermediate layer ML disposed on the first electrodes ANE in the openings OP (901 and 902) of neighboring pixels (e.g., PX1 and PX2) may extend onto an upper surface of the pixel defining layer PDL, but may be electrically disconnected from each other on and/or around the heating wirings 910 on the pixel defining layer PDL. The intermediate layer ML commonly covers the first electrodes ANE in the openings OP (901 and 902) of neighboring pixels (e.g., PX1 and PX2) and may extend onto the upper surface of the pixel defining layer PDL, but may be electrically disconnected on the pixel defining layer PDL between neighboring pixels (e.g., PX1 and PX2) by the heating wirings 910.

The electrical disconnection of the intermediate layer ML described in this disclosure may be interpreted as follows. The intermediate layer ML may include multiple layers as described with reference to FIGS. 6 and 7, and all of the layers may be electrically disconnected on the heating wirings 910 (or around the heating wirings 910). However, the disclosure may not be limited thereto. For example, at least some conductive layers among the layers included in the intermediate layer ML may be electrically disconnected on the heating wirings 910 (or around the heating wirings 910). The at least some conductive layers may include at least one of a hole injection layer HIL, a hole transport layer HTL, an electron transport layer ETL, a charge generation layer CGL, and a P-doped hole injection layer PHIL.

A second electrode CAE may be disposed on the intermediate layer ML in the openings OP (901 and 902) of the first pixel PX1 and the second pixel PX2. The second electrode CAE disposed on the intermediate layer ML in the openings OP (901 and 902) of the first pixel PX1 and the second pixel PX2 may extend onto the pixel defining layer PDL to cover the intermediate layer ML and the heating wiring 910 exposed during a process by the electrical disconnection of the intermediate layer ML. Therefore, the second electrode CAE may be continuous while covering the intermediate layer ML in the openings OP of the pixel defining layer PDL and covering the intermediate layer ML and the heating wirings 910 between neighboring pixels (e.g., PX1 and PX2).

As described above, the second electrode CAE may be commonly disposed in multiple pixels PX and be continuously electrically connected between neighboring pixels (e.g., PX1 and PX2). On the other hand, the intermediate layer ML may be commonly disposed in multiple pixels PX but may be electrically disconnected between neighboring pixels (e.g., PX1 and PX2) by the heating wiring 910.

The continuous electrical connection of the second electrode CAE and the electrical disconnection of the intermediate layer ML will now be described in more detail.

According to an embodiment, a heating wiring 910 surrounding each of the openings OP (901 and 902) may be disposed on the pixel defining layer PDL disposed between neighboring pixels (e.g., PX1 and PX2). A first portion ML1 of the intermediate layer ML and a first portion CAE1 of the second electrode CAE covering the first portion ML1 of the intermediate layer ML may be disposed on the pixel defining layer PDL having the heating wiring 910. Here, the first portion ML1 of the intermediate layer ML may be electrically disconnected around the heating wiring 910 from a second portion ML2 of the intermediate layer ML disposed in the openings OP (901 and 902) of the pixel defining layer PDL. On the other hand, the first portion CAE1 of the second electrode CAE may be continuously electrically connected to a second portion CAE2 without being electrically disconnected in a vicinity of the heating wiring 910 from the second portion CAE2 of the second electrode CAE disposed in the openings OP (901 and 902) of the pixel defining layer PDL. Here, the second portion CAE2 of the second electrode CAE disposed in the openings OP (901 and 902) may be a portion that covers the second portion ML2 of the intermediate layer ML disposed in the openings OP (901 and 902).

Since the heating wiring 910 surrounds each of the openings OP (901 and 902) of the pixel defining layer PDL, a pair of heating wirings 911 and 912 may be disposed apart from each other on the pixel defining layer PDL disposed between neighboring pixels (e.g., PX1 and PX2). For example, a first heating wiring 911 surrounding the first opening 901 of the first pixel PX1 and a second heating wiring 912 surrounding the second opening 902 of the second pixel PX2 may be disposed on the pixel defining layer PDL disposed between neighboring pixels (e.g., PX1 and PX2). The first heating wiring 911 and the second heating wiring 912 may be spaced apart by a distance (e.g., predetermined or selectable distance) on the pixel defining layer PDL disposed between neighboring pixels (e.g., PX1 and PX2). Therefore, the intermediate layer ML on the pixel defining layer PDL which may be electrically disconnected from the intermediate layer ML in the openings OP may be substantially disposed between the first heating wiring 911 and the second heating wiring 912. For example, the first portion ML1 of the intermediate layer ML may be electrically disconnected from the second portion ML2 of the intermediate layer ML disposed in the openings OP (901 and 902) of the pixel defining layer PDL and may be disposed between the first heating wiring 911 and the second heating wiring 912.

According to an embodiment, the heating voltage supply wiring VHL may independently drive the first heating wiring 911 and the second heating wiring 912 surrounding neighboring pixels PX1 and PX2, respectively. To this end, the heating wirings 910 may be electrically connected one-to-one to the first electrodes ANE of the pixels PX. For example, the first heating wiring 911 surrounding the first pixel PX1 may be electrically connected to the first electrode ANE of the first pixel PX1 through first connection electrodes 921 disposed in first contact holes CT911. The second heating wiring 912 surrounding the second pixel PX2 may be electrically connected to the first electrode ANE of the second pixel PX2 through second connection electrodes 922 disposed in second contact holes CT912.

According to an embodiment, each of the first electrodes ANE may include a first portion ANE_P1 covered by the pixel defining layer PDL and a second portion ANE_P2 extending from the first portion ANE_P1 and disposed in an opening of the pixel defining layer PDL. The first portion ANE_P1 of each of the first electrodes ANE may be electrically connected to a heating wiring 910 through connection electrodes 920 in the pixel defining layer PDL. The first portion ANE_P1 of each of the first electrodes ANE in the pixel defining layer PDL may be electrically connected to a heating transistor (e.g., T5 of FIG. 5) included in a pixel driving circuit (e.g., PC of FIG. 5) through a contact hole (not illustrated) penetrating the wiring layer 602. Each of the first electrodes ANE may receive a joule heating voltage VJH from the heating transistor T5 and may transmit the received joule heating voltage VJH to the heating wiring 910 through the connection electrodes 920.

To electrically disconnect the intermediate layer ML by applying the joule heating voltage VJH to the heating wirings 910, the heating wirings 910 need to be heated to a high temperature of about 400° C. or higher. To this end, it may be necessary to design the resistance of the heating wirings 910 to be relatively high. According to an embodiment, a first metal that forms the heating wirings 910, a second metal that forms the connection electrodes 920, and a third metal that forms the first electrodes ANE may be different metals. Here, the resistance of the first metal may be greater than the resistance of the second metal, and the resistance of the second metal may be greater than the resistance of the third metal.

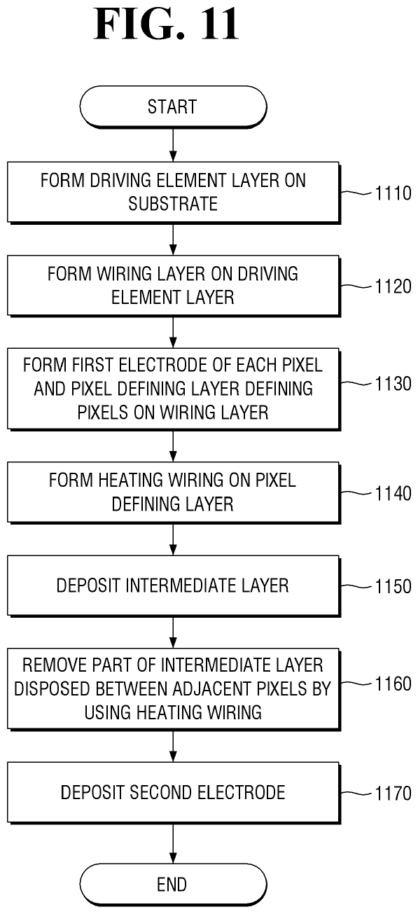

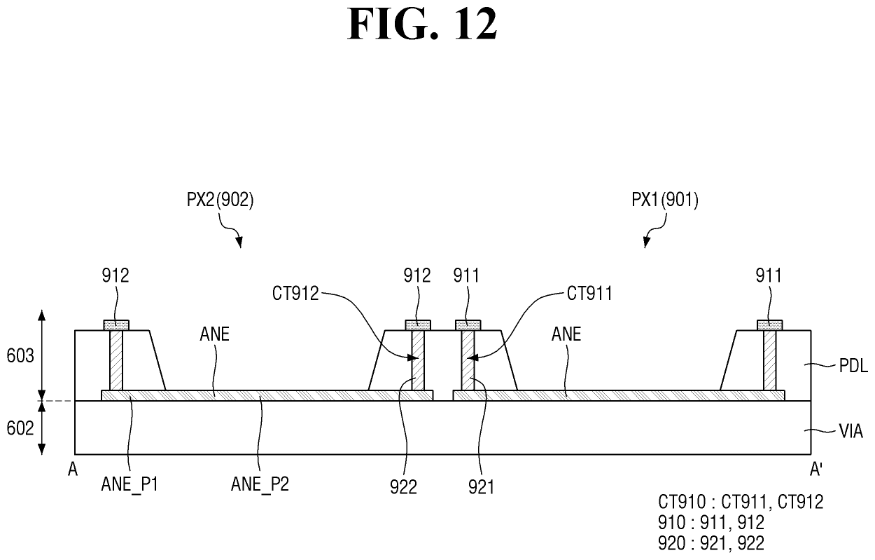

FIG. 11 is a flowchart illustrating a method of manufacturing the display panel 110 illustrated in FIG. 10. FIGS. 12 through 15 are schematic cross-sectional views sequentially illustrating a method of manufacturing a display panel 110 according to an embodiment.

The method of manufacturing the display panel 110 according to the embodiment will now be described with reference to FIGS. 11 through 15. The following description may be about only some of the processes of manufacturing the display panel 110, and processes for forming the elements described in this disclosure may be additionally performed before or after each operation described below. Processes of manufacturing the display panel 110 may be additionally performed before or after each operation described below.

Referring to FIG. 11, in operation 1110, a driving element layer 601 may be formed on a substrate 200. The driving element layer 601 may include MOSFETs MOS described with reference to FIG. 6. The driving element layer 601 may include a display driving circuit 210 (see FIG. 2) and pixel driving circuits PC.

Referring to FIG. 11, in operation 1120, a wiring layer 602 may be formed on the driving element layer 601. The wiring layer 602 may include insulating layers VIA sequentially stacked on each other and on the driving element layer 601, connection electrodes CE at least partially penetrating the insulating layers VIA, and multiple wirings.

Referring to FIG. 11, in operation 1130, a first electrode ANE of each pixel and a pixel defining layer PDL defining the pixels may be formed on the wiring layer 602. A portion (i.e., a second portion ANE_P2) of each first electrode ANE may be exposed during a process of forming an opening OP in the pixel defining layer PDL. Both ends (i.e., a first portion ANE_P1) of each first electrode ANE may be covered by the pixel defining layer PDL.

Referring to FIGS. 11 and 12, in operation 1140, contact holes CT910 penetrating the pixel defining layer PDL may be formed, and connection electrodes 920 electrically connected to the first electrodes ANE may be formed by filling the contact holes CT910. Then, a heating wiring 910 may be formed on the pixel defining layer PDL to cover the connection electrodes 920 and surround each opening OP of the pixel defining layer PDL. Here, a first metal that forms the heating wiring 910, a second metal that forms the connection electrodes 920, and a third metal that forms the first electrodes ANE may be different metals. The resistance of the first metal may be greater than the resistance of the second metal, and the resistance of the second metal may be greater than the resistance of the third metal.

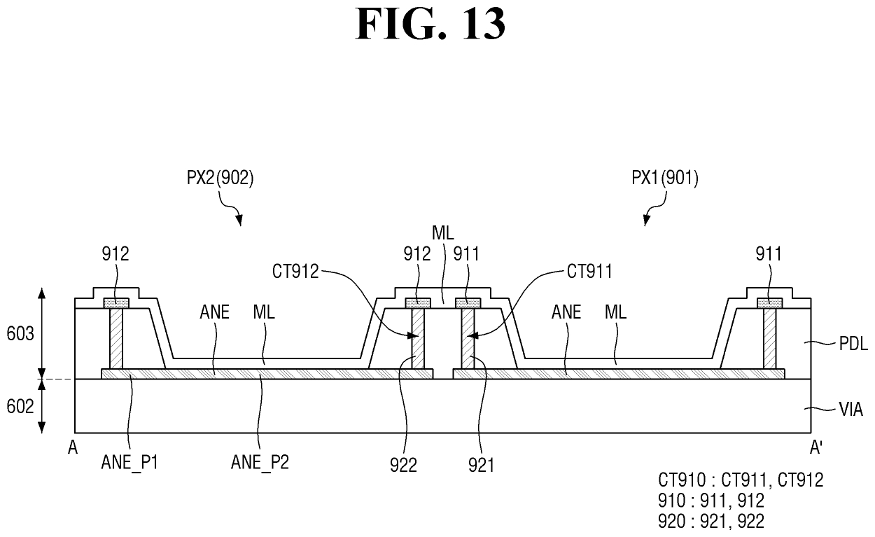

Referring to FIGS. 11 and 13, in operation 1150, an intermediate layer ML may be deposited. For example, the intermediate layer ML may be deposited not only in the openings OP of the pixel defining layer PDL but also on the pixel defining layer PDL between neighboring pixels (e.g., PX1 and PX2) by using an open mask (not illustrated). Accordingly, the intermediate layer ML may cover the first electrode ANE in each opening OP of the pixel defining layer PDL and cover the heating wirings 910 disposed on the pixel defining layer PDL.

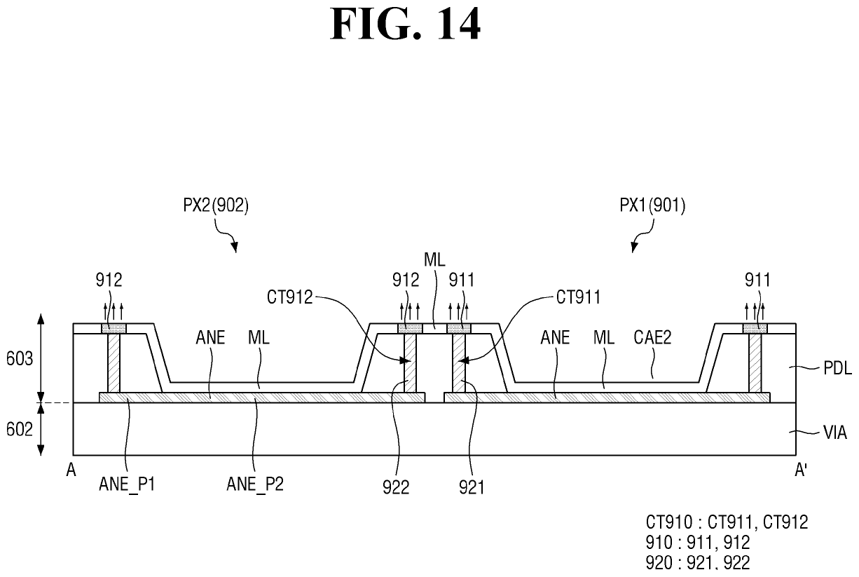

Referring to FIGS. 11 and 14, in operation 1160, all or at least a portion of the intermediate layer ML disposed between neighboring pixels (e.g., PX1 and PX2) may be removed using the heating wirings 910. To this end, heating transistors (e.g., T5 of FIG. 5) included in the pixel driving circuits PC may apply a joule heating voltage VJH to the first electrodes ANE, and the joule heating voltage VJH applied to the first electrodes ANE may be transmitted to the heating wirings 910 through the connection electrodes 920. The heating wirings 910 may be heated to a high temperature of about 400° C. or higher by the received joule heating voltage VJH. All or at least a portion of the intermediate layer ML deposited on the heating wirings 910 may be removed due to the high temperature of the heating wirings 910.

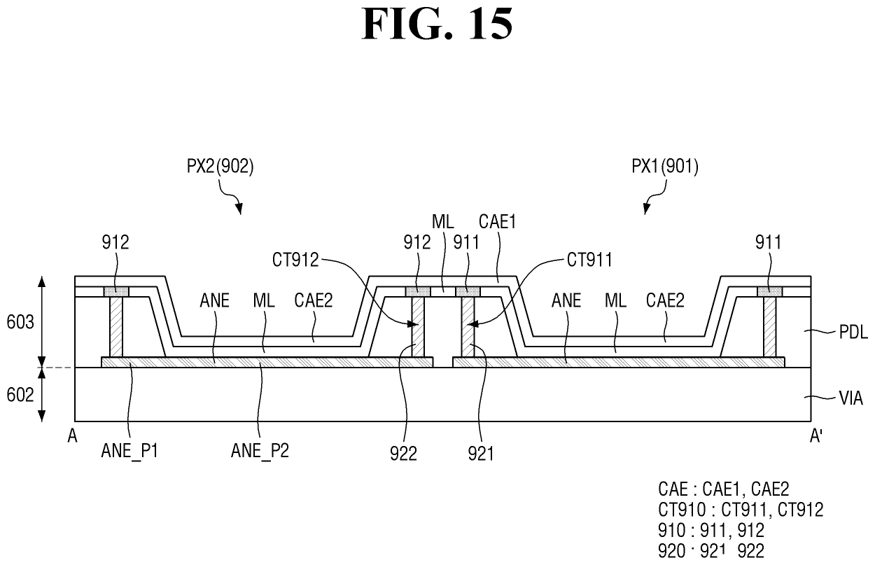

Referring to FIGS. 11 and 15, in operation 1170, a second electrode CAE may be deposited. For example, the second electrode CAE may be deposited not only in the openings OP of the pixel defining layer PDL but also on the pixel defining layer PDL disposed between neighboring pixels (e.g., PX1 and PX2) by using an open mask. Accordingly, the second electrode CAE may cover the intermediate layer ML in each opening OP of the pixel defining layer PDL and cover the intermediate layer ML and the heating wirings 910 disposed on the pixel defining layer PDL.

In the method of manufacturing the display panel 110 described with reference to FIGS. 11 through 15, the process of removing all or part of the intermediate layer ML using the heating wirings 910 may be performed before the operation of depositing the second electrode CAE. However, the disclosure may not be limited thereto. For example, the process of removing all or part of the intermediate layer ML using the heating wirings 910 may also be performed after the operation of depositing the second electrode CAE.

A method of performing the process of removing all or part of the intermediate layer ML using the heating wirings 910 after the operation of depositing the second electrode CAE and a display panel 110 manufactured using the method will now be described.

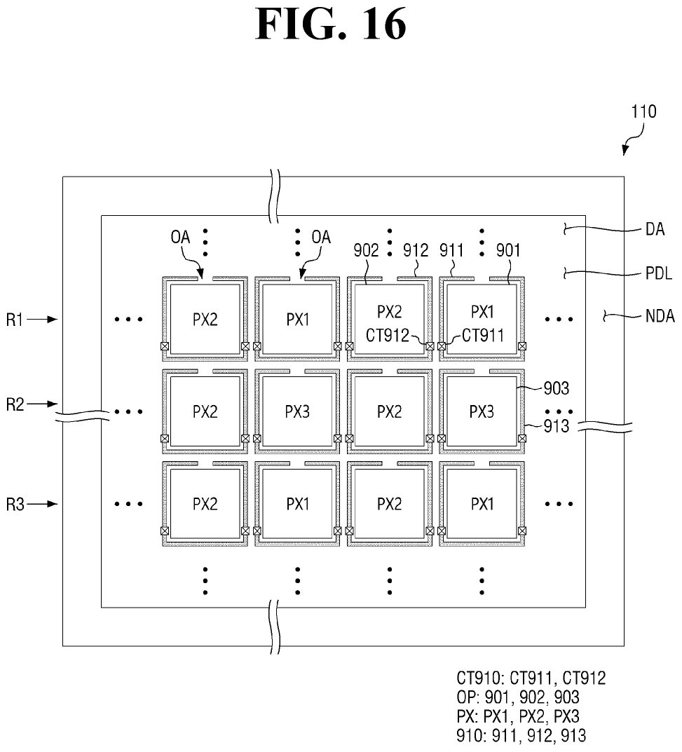

FIG. 16 illustrates an embodiment in which a heating wiring 910 illustrated in FIG. 9 may include an open slit area OA in a specific lateral direction of each pixel. In the following description of the embodiment of FIG. 16, overlapping descriptions with those of the embodiment of FIG. 9 will be omitted, and only differences of the embodiment of FIG. 16 from the embodiment of FIG. 9 will be described.

The embodiment of FIG. 16 may be different from the embodiment of FIG. 9 in that a heating wiring 910 may include an open slit area OA without completely surrounding each opening OP of a pixel defining layer PDL. For example, in case that viewed in a normal direction perpendicular to an upper surface of a substrate 200, the heating wiring 910 may surround each opening OP of the pixel defining layer PDL, but may include the open slit area OA open in a specific lateral direction. In the illustrated example, the open slit area OA may be located in a first lateral direction (e.g., an upper side in FIG. 16) of each pixel, but the disclosure may not be limited thereto.

According to an embodiment, the open slit area OA may be defined as an area in which the heating wiring 910 may not be disposed. Since the heating wiring 910 may not be disposed in the open slit area OA, an intermediate layer ML and a second electrode CAE of a light emitting element LEL may be continuous in the open slit area OA without being electrically disconnected. For example, the intermediate layer ML located outside each heating wiring 910 may be electrically connected to the intermediate layer ML located inside each heating wiring 910 (e.g., each opening OP of the pixel defining layer PDL) through the open slit area OA. Similarly, the second electrode CAE located outside each heating wiring 910 may be electrically connected to the second electrode CAE located inside each heating wiring 910 (e.g., each opening OP of the pixel defining layer PDL) through the open slit area OA. Therefore, the intermediate layer ML and the second electrode CAE may be continuous in a vicinity of the open slit area OA without being electrically disconnected.

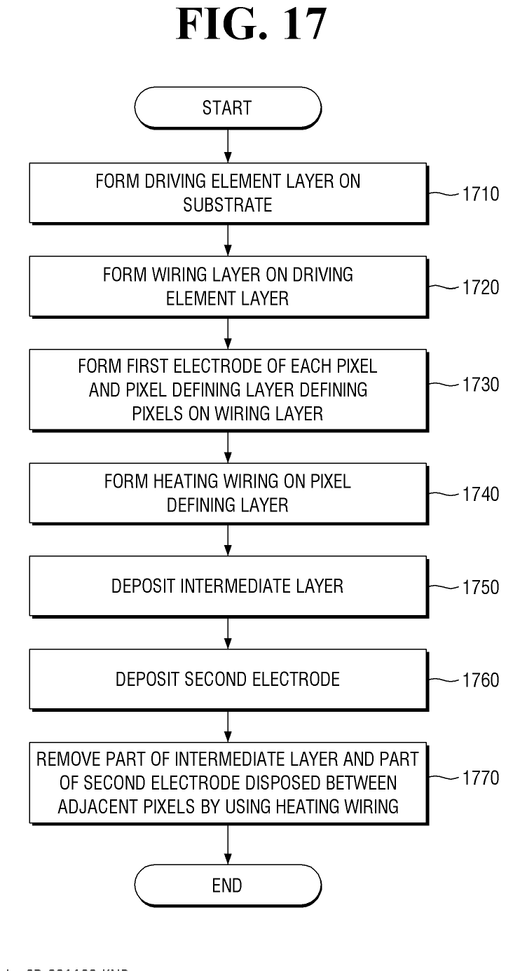

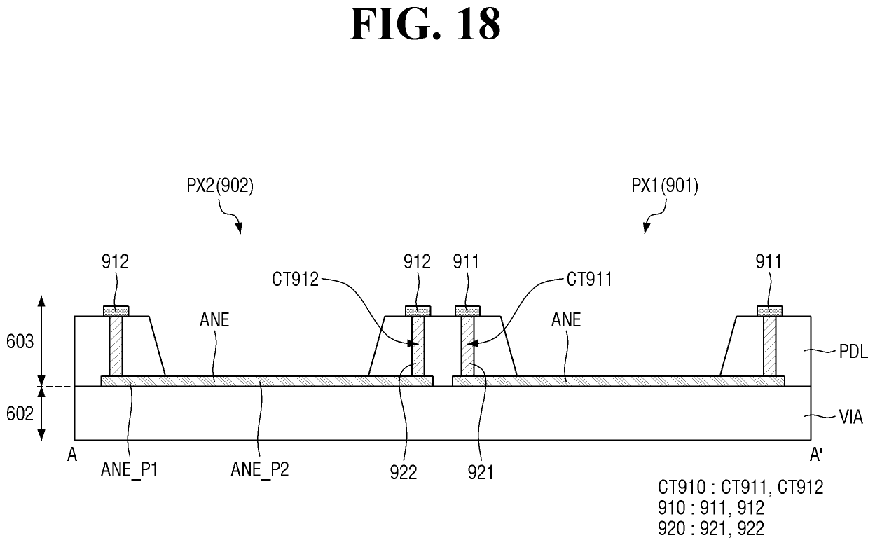

FIG. 17 is a flowchart illustrating a method of manufacturing the display panel 110 illustrated in FIG. 16. FIGS. 18 through 21 are schematic cross-sectional views sequentially illustrating a method of manufacturing a display panel 110 according to an embodiment.

The method of manufacturing the display panel 110 according to the embodiment will now be described with reference to FIGS. 17 through 21. The following description may be about only some of the processes of manufacturing the display panel 110, and processes for forming the elements described in this disclosure may be additionally performed before or after each operation described below. Processes of manufacturing the display panel 110 may be additionally performed before or after each operation described below.

Referring to FIG. 17, in operation 1710, a driving element layer 601 may be formed on a substrate 200. The driving element layer 601 may include MOSFETs MOS described with reference to FIG. 6. The driving element layer 601 may include a display driving circuit 210 (see FIG. 2) and pixel driving circuits PC. Operation 1710 may be substantially the same as operation 1110 described with reference to FIG. 11.

Referring to FIG. 17, in operation 1720, a wiring layer 602 may be formed on the driving element layer 601. The wiring layer 602 may include insulating layers VIA sequentially stacked on the driving element layer 601, connection electrodes CE at least partially penetrating the insulating layers VIA, and multiple wirings.

Referring to FIG. 17, in operation 1730, a first electrode ANE of each pixel and a pixel defining layer PDL defining the pixels may be formed on the wiring layer 602. A portion (i.e., a second portion ANE_P2) of each first electrode ANE may be exposed during a process of forming an opening OP in the pixel defining layer PDL. Both ends (i.e., a first portion ANE_P1) of each first electrode ANE may be covered by the pixel defining layer PDL. Operation 1730 may be substantially the same as operation 1130 described with reference to FIG. 11.

Referring to FIGS. 17 and 18, in operation 1740, contact holes CT910 penetrating the pixel defining layer PDL may be formed, and connection electrodes 920 electrically connected to the first electrodes ANE may be formed by filling the contact holes CT910. Then, a heating wiring 910 may be formed on the pixel defining layer PDL to cover the connection electrodes 920 and surround each opening OP of the pixel defining layer PDL. Here, a first metal that forms the heating wiring 910, a second metal that forms the connection electrodes 920, and a third metal that forms the first electrodes ANE may be different metals. The resistance of the first metal may be greater than the resistance of the second metal, and the resistance of the second metal may be greater than the resistance of the third metal. In operation 1740, the heating wiring 910 may be formed to have an open slit area OA without completely surrounding each opening OP of the pixel defining layer PDL.

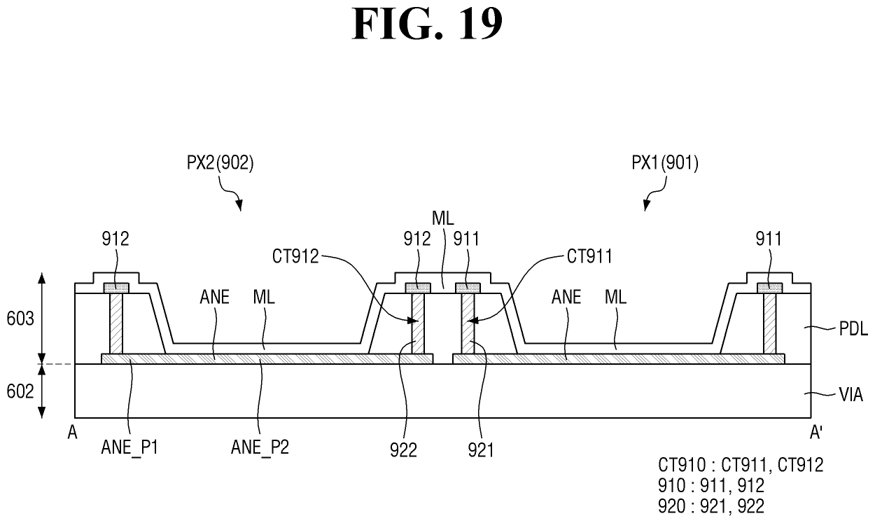

Referring to FIGS. 17 and 19, in operation 1750, an intermediate layer ML may be deposited. For example, the intermediate layer ML may be deposited not only in the openings OP of the pixel defining layer PDL but also on the pixel defining layer PDL between neighboring pixels (e.g., PX1 and PX2) by using an open mask (not illustrated). Accordingly, the intermediate layer ML may cover the first electrode ANE in each opening OP of the pixel defining layer PDL and cover the heating wirings 910 disposed on the pixel defining layer PDL. Operation 1750 may be substantially the same as operation 1150 described with reference to FIG. 11.

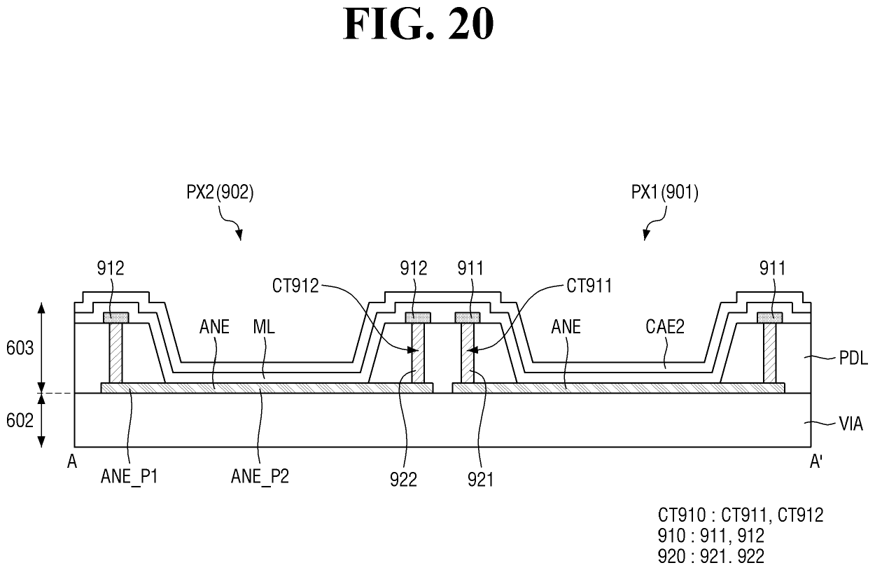

Referring to FIGS. 17 and 20, in operation 1760, a second electrode CAE may be deposited. For example, the second electrode CAE may be deposited not only in the openings OP of the pixel defining layer PDL but also on the pixel defining layer PDL disposed between neighboring pixels (e.g., PX1 and PX2) by using an open mask (not illustrated). Accordingly, the second electrode CAE may cover the intermediate layer ML in each opening OP of the pixel defining layer PDL and cover the intermediate layer ML disposed on the pixel defining layer PDL.

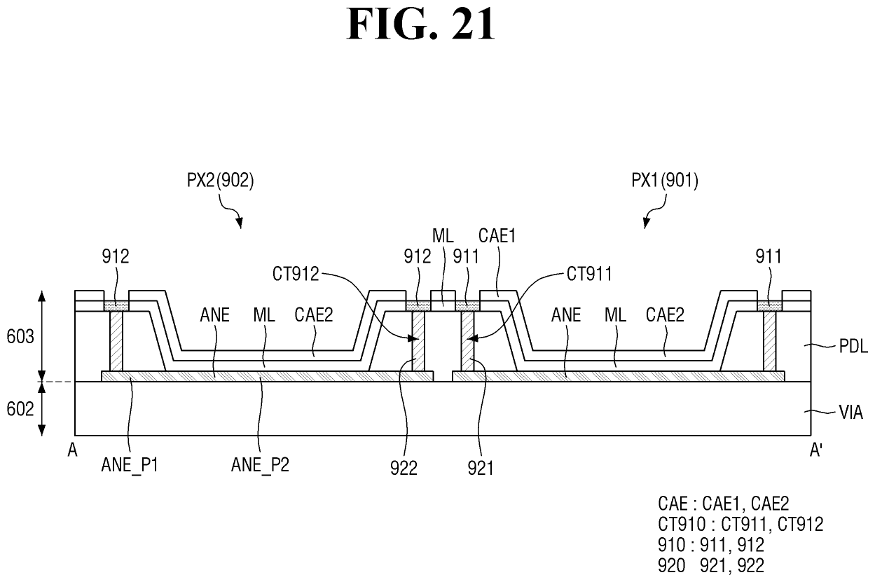

Referring to FIGS. 17 and 21, in operation 1770, all or at least a portion of the intermediate layer ML and the second electrode CAE disposed between neighboring pixels (e.g., PX1 and PX2) may be removed using the heating wirings 910. To this end, heating transistors (e.g., T5 of FIG. 5) included in the pixel driving circuits PC may apply a joule heating voltage VJH to the first electrodes ANE, and the joule heating voltage VJH applied to the first electrodes ANE may be transmitted to the heating wirings 910 through the connection electrodes 920. The heating wirings 910 may be heated to a high temperature of about 400° C. or higher by the received joule heating voltage VJH. The intermediate layer ML and the second electrode CAE deposited on the heating wirings 910 may be removed due to the high temperature of the heating wirings 910. Accordingly, the intermediate layer ML and the second electrode CAE may be electrically disconnected around the heating wirings 910. The second electrode CAE may be electrically discontinuous around the heating wirings 910 but may be electrically continuous in the open slit areas OA.

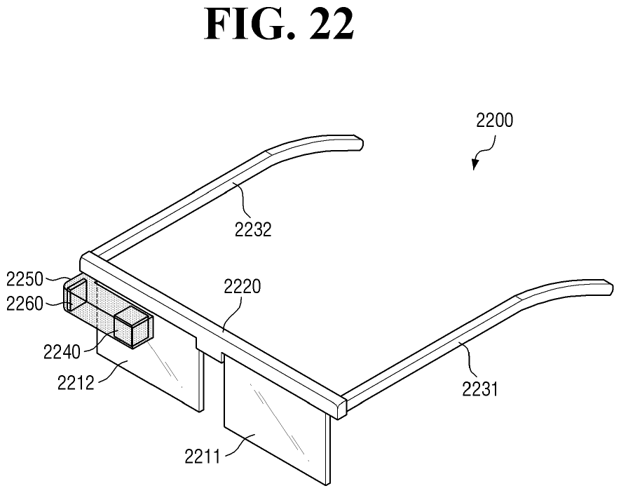

FIG. 22 is an example view of a wearable device including a display device according to an embodiment.

A display device 10 according to an embodiment may be a display device 2260 included in a mobile electronic device. The display device 10 according to the embodiment may be included in a wearable device that may be developed in the form of glasses or a helmet and forms a focus at a short distance from a user's eyes. For example, the wearable device may be an HMD or augmented reality (AR) glasses. Such a wearable device provides an AR screen or a virtual reality (VR) screen to a user.

FIG. 22 illustrates a VR device 2200 to which a display device 2260 according to an embodiment has been applied. Here, the display device 2260 may be, for example, a display device 2260 including the elements of FIGS. 1 through 21 described above.

Referring to FIG. 22, the VR device 2200 according to an embodiment may be an AR device in the form of glasses. The VR device 2200 according to the embodiment may include the display device 2260, a left lens 2211, a right lens 2212, a support frame 2220, eyeglass frame legs 2231 and 2232, a reflective member 2240, and an accommodating part 2250.

The accommodating part 2250 may include the display device 2260 and the reflective member 2240. An image displayed on the display device 2260 may be reflected by the reflective member 2240 and provided to a user's right eye through the right lens 2212. Accordingly, the user may view a VR image displayed on the display device 2260 through the right eye.

Although the accommodating part 2250 may be disposed at a right end of the support frame 2220 in FIG. 22, the disclosure may not be limited thereto. For example, the accommodating part 2250 may also be disposed at a left end of the support frame 2220. An image displayed on the display device 2260 may be reflected by the reflective member 2240 and provided to the user's left eye through the left lens 2211. Accordingly, the user may view a VR image displayed on the display device 2260 through the left eye. The accommodating part 2250 may be disposed at both the right end and the left end of the support frame 2220. The user may view a VR image displayed on the display device 2260 through both the left eye and the right eye.

In a display device according to embodiments and a mobile electronic device including the same, at least a portion of an intermediate layer disposed between a pixel electrode and a common electrode may be electrically disconnected between adjacent pixels. Therefore, leakage current and color crosstalk can be prevented.

However, the effects of the disclosure may not be restricted to the one set forth herein. The above and other effects of the disclosure will become more apparent to one of daily skill in the art to which the disclosure pertains by referencing the claims.

In concluding the detailed description, those skilled in the art will appreciate that many variations and modifications can be made to the embodiments without substantially departing from the principles of the invention. Therefore, the disclosed embodiments are used in a generic and descriptive sense only and not for purposes of limitation.

What is claimed is:

1. A display device comprising:
a substrate;
a driving element layer disposed on the substrate; and
a light emitting element layer disposed on the driving element layer,
wherein the light emitting element layer comprises:
a pixel defining layer including a plurality of openings defining a corresponding plurality of pixels;
a first electrode disposed in each of the plurality of pixels and comprising a first portion covered by the pixel defining layer and a second portion extending from the first portion and corresponding to one of the openings;
a heating wiring disposed on an upper surface of the pixel defining layer to surround at least a portion of each of the plurality of openings;
a connection electrode connecting the heating wiring and the first portion of the first electrode through a contact hole penetrating the pixel defining layer;
an intermediate layer covering the second portion of the first electrode and the pixel defining layer disposed between neighboring pixels, the intermediate layer including an electrically disconnected portion corresponding to the heating wiring in a plan view; and
a second electrode being continuous and covering portions of the intermediate layer disposed in the openings of each of the pixels and covering portions of the intermediate layer and the heating wiring disposed between the neighboring pixels.

2. The display device of claim 1, wherein the driving element layer comprises a joule heating driver disposed to correspond to a non-display area of the substrate and configured to sequentially supply a heating scan signal to a plurality of heating scan wirings disposed in a display area of the substrate.

3. The display device of claim 2, wherein the driving element layer further comprises a switching circuit disposed to correspond to the non-display area of the substrate and configured to supply a joule heating voltage to a plurality of heating voltage supply wirings disposed in the display area of the substrate in synchronization with a timing at which the joule heating driver outputs the heating scan signal.

4. The display device of claim 3, wherein
the switching circuit comprises a plurality of switching transistors electrically connected one-to-one to the plurality of heating voltage supply wirings, and
each of the plurality of switching transistors is turned on in response to a heating control signal and configured to output the joule heating voltage in case of being turned on.

5. The display device of claim 4, wherein the heating control signal is synchronized with the heating scan signal.

6. The display device of claim 3, wherein the heating voltage supply wirings intersect the heating scan wirings.

7. The display device of claim 3, wherein
the driving element layer further comprises a pixel driving circuit disposed in the display area of the substrate to correspond to each of the pixels, and
the pixel driving circuit comprises:
a driving transistor supplying a designated driving current to a first node electrically connected to the first electrode based on a data signal input from a data line; and
a heating transistor turned on in response to the heating scan signal input from a heating scan wiring and supplying the joule heating voltage input from a heating voltage supply wiring to the first node in case of being turned on.

8. The display device of claim 7, wherein the heating wiring is configured to receive the joule heating voltage via the first electrode and the connection electrode.

9. The display device of claim 8, wherein a resistance of the heating wiring is greater than each of a resistance of the first electrode and a resistance of the connection electrode.

10. The display device of claim 1, wherein
the intermediate layer comprises at least one conductive layer including a portion electrically disconnected at a location corresponding to the heating wiring, and
the at least one conductive layer comprises a layer selected from a hole injection layer, a hole transport layer, an electron transport layer, a charge generation layer, and a P-doped layer.

11. The display device of claim 1, wherein
in a plan view, the heating wiring surrounds each of the openings in the pixel defining layer, and
the heating wiring comprises an open slit area open at a specific lateral direction.

12. The display device of claim 11, wherein the intermediate layer and the second electrode are continuous without being electrically disconnected at a location corresponding to the open slit area.

13. A mobile electronic device comprising a display panel, wherein the display panel comprises:
a substrate;
a driving element layer disposed on the substrate; and
a light emitting element layer disposed on the driving element layer,
wherein the light emitting element layer comprises:
a pixel defining layer including a plurality of openings defining a corresponding plurality of pixels;
a first electrode disposed in each of the plurality of pixels and comprising a first portion covered by the pixel defining layer and a second portion extending from the first portion and corresponding to one of the openings;
a heating wiring disposed on an upper surface of the pixel defining layer to surround at least a portion of each of the plurality of openings;
a connection electrode connecting the heating wiring and the first portion of the first electrode through a contact hole penetrating the pixel defining layer;
an intermediate layer covering the second portion of the first electrode and the pixel defining layer disposed between neighboring pixels, the intermediate layer including an electrically disconnected portion corresponding to the heating wiring in a plan view; and
a second electrode being continuous and covering portions of the intermediate layer disposed in the openings of each of the pixels and covering portions of the intermediate layer and the heating wiring disposed between the neighboring pixels.

14. The mobile electronic device of claim 13, wherein the driving element layer comprises a joule heating driver disposed to correspond to a non-display area of the substrate and configured to sequentially supply a heating scan signal to a plurality of heating scan wirings disposed in a display area of the substrate.

15. The mobile electronic device of claim 14, wherein the driving element layer further comprises a switching circuit disposed to correspond to the non-display area of the substrate and configured to supply a joule heating voltage to a plurality of heating voltage supply wirings disposed in the display area of the substrate in synchronization with a timing at which the joule heating driver outputs the heating scan signal.

16. The mobile electronic device of claim 15, wherein
the switching circuit comprises a plurality of switching transistors electrically connected one-to-one to the plurality of heating voltage supply wirings, and
each of the plurality of switching transistors is turned on in response to a heating control signal and configured to output the joule heating voltage in case of being turned on.

17. The mobile electronic device of claim 16, wherein the heating control signal is synchronized with the heating scan signal.

18. The mobile electronic device of claim 15, wherein the heating voltage supply wirings intersect the heating scan wirings.

19. The mobile electronic device of claim 15, wherein
the driving element layer further comprises a pixel driving circuit disposed in the display area of the substrate to correspond to each of the pixels, and the pixel driving circuit comprises:
a driving transistor supplying a designated driving current to a first node electrically connected to the first electrode based on a data signal input from a data line; and
a heating transistor turned on in response to the heating scan signal input from a heating scan wiring and supplying the joule heating voltage input from a heating voltage supply wiring to the first node in case of being turned on.

20. The mobile electronic device of claim 19, wherein the heating wiring is configured to receive the joule heating voltage via the first electrode and the connection electrode.
